(19) United States
(12) Patent Application Publication
(10) Pub. No.: US 2023/0260744 A1
(43) Pub. Date: Aug. 17, 2023

(54) METHOD FOR PRODUCING A SAMPLE ON AN OBJECT, COMPUTER PROGRAM PRODUCT, AND MATERIAL PROCESSING DEVICE FOR CARRYING OUT THE METHOD

(71) Applicant: Carl Zeiss Microscopy GmbH, Jena (DE)

(72) Inventor: Heiko Stegmann, Dresden (DE)

(73) Assignee: Carl Zeiss Microscopy GmbH, Jena (DE)

(21) Appl. No.: 17/974,702

(22) Filed: Oct. 27, 2022

(30) Foreign Application Priority Data
Oct. 28, 2021 (DE) 102021128117.2

(51) Int. Cl. H01J 37/28; H01J 37/22; H01J 37/145; H01J 37/244; H01J 37/304; G01N 23/2251; H01J 37/147

(52) U.S. Cl. CPC H01J 37/28; H01J 37/226; H01J 37/145; H01J 37/244; H01J 37/304; G01N 23/2251; H01J 37/1475; H01J 37/1477; H01J 2237/1505

(57) ABSTRACT

The invention relates to a method for producing a sample on an object using a material processing device. The invention further relates to a computer program product and a material processing device for carrying out the method. The method comprises guiding a light beam over a surface of the object in a first direction along a first line, with material of the object being ablated when the light beam is guided over the surface of the object, changing the first direction into a second direction, guiding the light beam over the surface of the object in the second direction along a second line, with material of the object being ablated when the light beam is guided over the surface of the object along the second line, wherein the light beam is provided in pulsed fashion and is guided onto the surface of the object in such a way that the light beam ablates material from the object in a first operational state of the light beam device and that the light beam is not guided onto the object in a second operational state, and wherein the sample is produced in the first operational state by ablating material from the object.

### CROSS-REFERENCE TO RELATED APPLICATIONS

This application claims the priority of the German patent application No. 10 2021 128 117.2, filed on Oct. 28, 2021, which is incorporated herein by reference.

### TECHNICAL FIELD

This application relates to producing at least one sample on an object using a material processing device which, for example, includes a particle beam apparatus and relates to a computer program product and a material processing device for carrying out the same.

### BACKGROUND

Electron beam apparatuses, in particular a scanning electron microscope (also referred to as SEM below) and/or a transmission electron microscope (also referred to as TEM below), are used to examine objects (samples) in order to obtain knowledge with respect to the properties and the behavior under certain conditions.

In an SEM, an electron beam (also referred to as primary electron beam below) is generated using a beam generator and focused onto an object to be examined using a beam guiding system. The primary electron beam is guided in a raster manner over a surface of the object to be examined using a deflection device. Here, the electrons of the primary electron beam interact with the object to be examined. As a consequence of the interaction, in particular, electrons are emitted by the object (so-called secondary electrons) and electrons of the primary electron beam are backscattered (so-called backscattered electrons). The secondary electrons and backscattered electrons are detected and used for image generation. An image representation of the object to be examined is thus obtained. Further, interaction radiation, for example x-ray radiation and cathodoluminescent light, is generated as a consequence of the interaction. In particular, the interaction radiation is used to analyze the object.

In the case of a TEM, a primary electron beam is likewise generated using a beam generator and focused on an object to be examined using a beam guiding system. The primary electron beam passes through the object to be examined. When the primary electron beam passes through the object to be examined, the electrons of the primary electron beam interact with the material of the object to be examined. The electrons passing through the object to be examined are imaged onto a luminescent screen or onto a detector (for example a camera) by a system consisting of an objective and a projection unit. Here, imaging can also take place in the scanning mode of a TEM. Usually, such a TEM is referred to as STEM. Additionally, provision can be made for detecting electrons backscattered at the object to be examined and/or secondary electrons emitted by the object to be examined using a further detector in order to image an object to be examined.

Furthermore, it is known from the prior art to use combination apparatuses for examining objects, where both electrons and ions can be guided onto an object to be examined. By way of example, it is known to additionally equip an SEM with an ion beam column. An ion beam generator arranged in the ion beam column generates ions that are used for preparing an object (for example ablating material of the object or applying material to the object) or else for imaging. The SEM serves in this case for observing the preparation, but also for further examination of the prepared or unprepared object.

In a further known particle beam apparatus, applying material to the object is carried out for example using the feed of a gas. The known particle beam apparatus is a combination apparatus that provides both an electron beam and an ion beam. The particle beam apparatus includes an electron beam column and an ion beam column. The electron beam column provides an electron beam that is focused onto an object. The object is arranged in a sample chamber kept under vacuum. The ion beam column provides an ion beam that is likewise focused on the object. By way of example, a layer of the surface of the object is removed using the ion beam. After the layer has been removed, a further surface of the object is exposed. Using a gas feed device, a gaseous precursor substance—a so-called precursor—can be admitted into the sample chamber. It is known to form the gas feed device with an acicular device, which can be arranged quite close to a position of the object at a distance of up to a few hundred μm, such that the gaseous precursor substance can be guided to this position as accurately as possible and with a high concentration. As a result of the interaction of the ion beam with the gaseous precursor substance, a layer of a substance is deposited on the surface of the object. By way of example, it is known for gaseous phenanthrene to be admitted as gaseous precursor substance into the sample chamber using the gas feed device. Essentially a layer of carbon or a carbon-containing layer then deposits on the surface of the object. It is also known to use a gaseous precursor substance that includes metal in order to deposit a metal or a metal-containing layer on the surface of the object. However, the depositions are not limited to carbon and/or metals. Rather, any desired substance can be deposited on the surface of the object, for example semiconductors, non-conductors or other compounds. Furthermore, it is known for the gaseous precursor substance to be used for ablating material of the object upon interaction with a particle beam.

The application of material on the object and/or the ablation of material from the object is used for arranging a marking on the object, for example. In the prior art, the marking is used, for example, for positioning the electron beam and/or the ion beam.

The practice of generating a sample on an object using an ion beam apparatus is known, with the sample having a cylindrical form. By way of example, the diameter of such a sample can be less than 1 μm to several 100 μm. The height of such a sample can range from several 10 μm to approximately 1 mm.

Cylindrical samples are examined using known methods which are explained in the following.

The prior art teaches that the determination of micromechanical properties of the material of a cylindrical sample. By way of example, the deformation of the cylindrical sample is measured by exerting pressure on a face of the cylindrical sample. Such a measurement is carried out in a particle beam apparatus, in particular. To this end, the particle beam apparatus includes an appropriate “in situ” measurement device. The measurement results determined using this known method are used in mathematical models in order to determine the mechanical material properties of the material of the cylindrical sample. For this determination to be accurate, it is desirable for the sample to have a cylindrical shape, on which the mathematical models are based, to the greatest possible accuracy.

The prior art also teaches that the examination of a cylindrical sample using synchrotron radiation and, in the process, the generation of a sequence of projection images of the cylindrical sample from different directions. A three-dimensional structure of the interior of the cylindrical sample can be determined with high spatial resolution from the sequence of projection images. By way of example, such examinations are of interest when analyzing subcellular structures in biological samples. In this case it is also desirable for the sample to have a cylindrical shape that is as accurate as possible, in order to enable an artifact-free determination of the structure.

Further, the prior art also teaches that the examination of a cylindrical sample using x-ray radiation in order to generate a sequence of projection images of the cylindrical sample from different directions. A three-dimensional structure of the interior of the cylindrical sample can be determined with low to mid spatial resolution from the sequence of projection images. By way of example, such examinations are of interest in the analysis of defects of microelectronic components or for the analysis of the porosity of biological or geological samples. In this case it is also desirable for the sample to have a cylindrical shape that is as accurate as possible, in order to enable an artifact-free determination of the structure.

A cylindrical shape of samples that is as accurate as possible is also desirable for atom probe tomography. Atom probe tomography is a quantitative analyzing method for determining the distribution of elements in an object. In atom probe tomography, a sample is examined which has a tip with a tip radius of the order of 10 nm to 100 nm, for example. An electric field with a voltage whose field strength does not suffice to bring about a detachment of atoms from the Up is applied to this tip. Then a short voltage pulse is applied to the tip in addition to the aforementioned voltage. This causes an increase in the field strength, the latter then being sufficient to detach individual ions at the tip by field evaporation. The use of a short laser pulse as an alternative to the short voltage pulse is also known. An atom that has been detached as an ion is steered to a position-sensitive detector by the electric field. Since the time of the voltage pulse or the laser pulse is known, the time at which the ion was detached from the tip is also known. A time of flight of the ion from the tip to the position-sensitive detector, which is to be determined, then can be used to determine the mass of the ion, more precisely the ratio of mass to charge number of the ion. The x- and y-position of the atom at the tip can be determined from the location of incidence of the ion on the position-sensitive detector. The z-position of the atom in the tip is determined with knowledge of the evaporation sequence carried out. Expressed differently, ions striking the position-sensitive detector at a later time are arranged further within the tip than ions striking the position-sensitive, detector at an earlier time. By way of example, the sample with the tip may have been produced electrochemically. Producing the sample with the tip in a combination apparatus that has an electron beam column and an ion beam column is also known. In particular, provision is made for the tip of the sample to be produced by ablating material from the object using an ion beam. Imaging with the electron beam is used to observe the ablation of the material. The more the sample has already been embodied to be cylindrical, the less material needs to be removed from the sample during the ablation using the ion beam in order to produce the tip. The less material has to be ablated, the more samples can be produced within a given time.

Methods for producing a cylindrical sample known from the prior art are discussed below.

By way of example, for the purposes of producing the cylindrical sample, the practice of cutting the sample out of a large object using an ion beam guided substantially perpendicular to the surface of the object is known. Alternatively, a piece of material which has already been cut out of a large object is processed using the ion beam which is guided substantially perpendicular to the surface of the piece of material for the purposes of producing the cylindrical sample. In this case, the ion beam is moved about a center along circular trajectories with reducing radius. Using the known method, it is possible to successively produce a plurality of cylindrical samples in a single operation. However, it has been found to be difficult to create a truly cylindrical sample using this known method. Rather, a sample produced using the known method has greater resemblance to a sample with a conical frustum form. To reduce the angle between a generatrix and a conical axis of the conical frustum form, and hence to bring the form of the sample closer to a cylindrical shape, consideration has been given to continuously tilting the sample in relation to the ion beam during the production of the sample using the known method. However, it has been found that the tilt of the sample should be precise, and this would only be obtainable using a very complicated mechanism. For this reason, it is known to bring the sample closer to the cylindrical shape by virtue of choosing an ion beam with a very low beam current of a few nanoampere in a last processing step, as it is known that when material is ablated from the conical frustum form of the sample using an ion beam, the angle between the generatrix and the conical axis of the conical frustum form of the sample reduces in the case of a low beam current. An essentially cylindrical sample is produced as a result of the last processing step. However, only little material is ablated in the case of a low beam current, and so the production of such a sample may take up to several hours.

Further, for the purposes of producing the cylindrical sample, the practice of cutting the sample out of a large object using an ion beam guided substantially parallel to the surface of the object is known. Alternatively, a piece of material which has already been cut out of a large object is processed using the ion beam which is guided substantially parallel to the surface of the piece of material for the purposes of producing the cylindrical sample. In this case, the ion beam is moved firstly continuously and secondly up and down in the direction perpendicular to the surface of the object or piece of material. Additionally, the object or piece of material is rotated about an axis which is arranged at the location of the subsequent sample and oriented perpendicular to the surface of the object or piece of material. A virtually cylindrical form of the sample is obtained using this known method. However, this known method is very time-consuming on account of the aforementioned rotational movement and the movement of the ion beam. The time to produce a cylindrical sample may take up to several hours. Further, the aforementioned, known method is not yet suitable for automation in relation to the production of several cylindrical samples in a single operation.

Moreover, a further method for producing the cylindrical sample is known, within the scope of which the cylindrical sample is cut out of an object using a laser beam of a laser beam device. To this end, the laser beam is moved about a center in spiral fashion with reducing radius. The time to produce a cylindrical sample takes a few seconds to a few minutes in this known method. However, it has been also found to be difficult to produce a virtually cylindrical sample using this known method. Rather, a sample produced using this known method has greater resemblance to a sample with a conical frustum form. To reduce the angle between a generatrix and a conical axis of the conical frustum form, and hence to bring the form of the sample closer to a cylindrical shape, consideration has been given to continuously tilting the sample in relation to the laser beam during the production of the sample using the known method. However, it has been found that the tilt of the sample should be precise, and this would only be obtainable using a very complicated mechanism. Although it would be possible to continually tilt the laser beam itself for the purposes of bringing the form of the sample closer to a cylindrical shape, a very accurate telecentric optical unit should be used in this case in order to accurately guide the laser beam. However, such optical units are quite expensive. For this reason, a different path has been taken in the known method for the purposes of creating the cylindrical form of the sample. The sample cut out using the laser beam is post-processed in such a way using an ion beam that a substantially cylindrical form of the sample is obtained. Since, usually, the current of the ion beam is chosen to be low in this case (for example, of the order of a few nanoampere), the post-processing takes quite a long time until the cylindrical form of the sample is obtained. Although the known method is suitable for producing a plurality of cylindrical samples in a single operation, the minimum distance between two cylindrical samples is limited on account of the spiral guidance of the laser beam, and so the number of producible cylindrical samples is likewise restricted.

### SUMMARY OF THE INVENTION

The system described herein relates to producing a sample on an object that is as cylindrical as possible or producing a plurality of cylindrical samples that is/are producible within a short period of time.

The system described herein produces at least one sample on an object using a material processing device which includes at least one light beam device that provides at least one light beam. Embodiments of the light beam device are discussed in more detail below. The material of the object can be processed using the material processing device so that at least one sample, more particularly a multiplicity of samples, is produced on the object. By way of example, the system described herein may be carried out in automated, partly automated or manual fashion. Therefore, individual, multiple or all method steps described herein, for example, may be carried out automatically and/or manually. In particular, the material processing device includes a particle beam apparatus, a mechanical ablation device, and/or an ion beam device. This is discussed in more detail below.

A light beam is guided over a surface of an object in a first direction along a first line. A guiding device for the light beam is used to guide the light beam. By way of example, the guiding device includes at least one mirror, at least one lens, a system of a plurality of mirrors, a system of a plurality of lenses, and/or a system of a plurality of mirrors and a plurality of lenses. Additionally or as an alternative, provision is made for the object to be arranged on a movable object stage and for the object to be moved in relation to the light beam. Expressed differently, there is a relative movement of the light beam with respect to the object in order to guide the light beam. The relative movement is provided by moving the light beam and/or by moving the object stage. Material of the object is ablated when the light beam is guided over the surface of the object. Consequently, the light beam interacts with the material of the object. On account of the interaction of the light beam with the material of the object, the material on the object is ablated such that the sample, or at least a part of the sample, is produced.

Further, the direction of the movement of the light beam may be changed according to the system described herein. Specifically, the first direction is changed into a second direction, with the first direction being changed into the second direction by rotating the first line about an axis of rotation on the surface of the object. The first direction and the second direction differ from one another. Then, the light beam is guided over the surface of the object in the second direction along a second line. Once again, material of the object is ablated when the light beam is guided over the surface of the object along the second line. Consequently, the light beam interacts with the material of the object while the light beam is guided along the second line. On account of the interaction of the light beam with the material of the object, material on the object is ablated such that the sample, or at least a part of the sample, is produced.

In the system described herein, provision is made for the light beam to be provided in pulsed fashion by the light beam device. By way of example, the light beam is provided with pulse durations of the order of picoseconds or femtoseconds. The light beam device has a first operational state and a second operational state. In the first operational state, the pulsed light beam is guided to the surface of the object in such a way that the light beam ablates the material from the object for the purposes of producing the sample or at least a part of the sample. The light beam is not guided to the object in the second operational state. Expressed differently, the second operational state is the state of the light beam device which occurs between the provision of the light beam for a first time interval and the provision of the light beam for a second time interval. Expressed yet again differently, the light beam is initially provided during the first time interval. Then there is a time interval during which the light beam is not provided. Subsequently, the light beam is provided in the second time interval. The sample or at least a part of the sample is produced in the first operational state using the ablation of material from the object on account of the interaction of the light beam with the object.

The system described herein is particularly well suited to the production of a sample that is as cylindrical as possible or of a plurality of cylindrical samples within a short period of time. By way of example, a sample whose side walls are aligned at right angles or virtually at right angles to a surface of the sample is producible using the system described herein. By way of example, the side walls are aligned so as to deviate by only up to 3° from the perpendicular alignment. In particular, the system described herein renders a sample with a high aspect ratio (i.e., a large ratio of height of the sample to the smallest lateral extent of the sample) producible. It has been found that the use of pulsed light beams from the light beam device allows a sample to be formed as cylindrical as possible. Moreover, it has been found that the system described herein allows good simultaneous production of a plurality of cylindrical samples. Once the cylindrical sample or the plurality of cylindrical samples has/have been produced, the plurality of cylindrical samples are separated from the object, for example, in an embodiment of the system described herein. The separation is implemented in particular using an ion beam which is provided by a particle beam apparatus. Subsequently, the cylindrical sample or the plurality of cylindrical samples is analyzed.

By way of example, micromechanical properties of the material of a cylindrical sample are determined. In particular, the deformation of the cylindrical sample is measured by exerting pressure on a face of the cylindrical sample. Such a measurement is carried out in a particle beam apparatus, for example. To this end, the particle beam apparatus includes an appropriate “in situ” measurement device. The measurement results determined are used in mathematical models in order to determine the mechanical material properties of the material of the cylindrical sample.

By way of example, a cylindrical sample is examined using synchrotron radiation and, in the process, a sequence of projection images of the cylindrical sample is created from different directions. A three-dimensional structure of the interior of the cylindrical sample can be determined with high spatial resolution from the sequence of projection images. By way of example, such examinations are of interest when analyzing subcellular structures in biological samples.

By way of example, a cylindrical sample is examined using x-ray radiation in order to create a sequence of projection images of the cylindrical sample from different directions. A three-dimensional structure of the interior of the cylindrical sample can be determined with low to mid spatial resolution from the sequence of projection images. By way of example, such examinations are of interest in the analysis of defects of microelectronic components or for the analysis of the porosity of biological or geological samples.

By way of example, the diameter of a produced cylindrical sample is between less than 1 μm and several 100 μm. The height of such a sample can range from several 10 μm to approximately 1 mm.

In an embodiment of the system described herein, provision is additionally or alternatively made for the sample to be a first sample. In the first operational state of the light beam device, at least one further sample in the form of a second sample is produced using ablating material from the object using the light beam. Expressed differently, it is not only a single sample that is produced using the system described herein but a plurality of samples are produced instead, for example the aforementioned first sample and the aforementioned second sample. Further embodiments with respect to the number of producible samples are explained in more detail below.

In a further embodiment of the system described herein, provision is additionally or alternatively made for the first sample (or at least a part of the first sample) to be produced first, and then the second sample (or at least a part of the second sample). As an alternative thereto, provision is made for the first sample (or at least a part of the first sample) and the second sample (or at least a part of the second sample) to be produced in a single work step of a method according to the system described herein.

In yet another embodiment of the system described herein, provision is additionally or alternatively made for the first sample to have a first face with a first center. Further, the second sample has a second face with a second center. In particular, provision is made for the first face and/or the second face to be aligned parallel or substantially parallel to the surface of the object. In this embodiment of the system described herein, provision is now made for the first sample and the second sample to be produced in such a way that the first center is at a distance from the second center, with the distance having at least one of the following features:
(i) the distance corresponds to a diameter or a multiple of the diameter of the light beam;

(ii) the distance is less than 900 μm, less than 800 μm, less than 700 μm, less than 600 μm, less than 500 μm, less than 400 μm, less than 300 μm, less than 200 μm, less than 100 μm, less than 80 μm, less than 60 μm, less than 50 μm, less than 30 μm, less than 20 μm, or less than 10 μm, for example.

By way of example, the diameter of the light beam is the diameter of the light beam at the focus or in the vicinity of the focus, in particular at a distance from the focus in a range of ±(30 μm to 50 μm). Additionally or as an alternative, the diameter of the light beam is the diameter of the light beam at the point of incidence of the light beam on the object or at the location where the material of the object on which the light beam is incident is processed.

Deliberations have shown that a cylindrical sample is able to be obtained particularly well if the distance corresponds to the diameter or a multiple of the diameter of the light beam.

By way of example, the distance is defined as set forth below. A first straight line, which is aligned perpendicular to the first face, runs through the first center. Moreover, a second straight line, which is aligned perpendicular to the second face, runs through the second center. The distance between the first sample and the second sample is the distance between the first straight line and the second straight line. By way of example, the distance is the length of a straight distance line, which intersects both the first straight line and the second straight line perpendicularly. As an alternative thereto, the distance is for example the minimum distance between the first straight line and the second straight line.

What is stated above may also be expressed, for example, as follows: The distance between the first sample and the second sample is less than 30 μm, less than 20 μm, or less than 10 μm. By way of example, the first sample has a first edge. Further, the second sample has a second edge. The distance between the first sample and the second sample is the distance between the first edge and the second edge. By way of example, the distance is the length of a straight distance line, which runs from a first point on the first edge to a second point on the second edge. In particular, the distance is for example the minimum distance between the first edge and the second edge.

In yet a further embodiment of the system described herein, provision is additionally or alternatively made for a first marking to be arranged on the first face of the first sample and/or for a second marking to be arranged on the second face. By way of example, the first marking and/or the second marking is/are arranged using the light beam and/or a particle beam, which is provided by a particle beam apparatus. The first marking and the second marking serve to render the first sample and the second sample uniquely identifiable.

In an embodiment of the system described herein, provision is additionally or alternatively made for the producible sample to be a part of a multiplicity of producible samples. In this embodiment according to the system described herein, provision is made for the multiplicity of samples to be produced by ablating material from the object using the light beam in the first operational state of the light beam device. In particular, provision is made for the multiplicity of samples to include at least 5 samples, at least 10 samples or at least 15 samples on the object. However, the invention is not restricted to the aforementioned number of samples. Instead, the multiplicity of samples may include any number of samples suitable for the invention.

In a further embodiment of the system described herein, provision is additionally or alternatively made for the individual samples of the multiplicity of samples to be respectively produced in succession in the first operational state of the light beam device. Expressed differently, one of the samples of the multiplicity of samples is produced first, followed by a further sample of the multiplicity of samples. The aforementioned is repeated until all samples of the multiplicity of samples have been produced. As an alternative, provision is made for a plurality of samples of the multiplicity of samples to be produced (or for at least in each case some of a plurality of samples of the multiplicity of samples to be produced) in a single work step of a method according to the system described herein. In a further alternative, provision is made for all samples of the multiplicity of samples to be produced (or for at least in each case some of all samples of the multiplicity of samples to be produced) in a single work step of a method according to the system described herein.

In yet a further embodiment of the system described herein, provision is additionally or alternatively made for each sample of the multiplicity of samples to have a respective face with a center. In particular, provision is made for each face to be aligned parallel or substantially parallel to the surface of the object. In this embodiment according to the system described herein, provision is made for the center of the face of at least one first sample of the multiplicity of samples to be at a distance from the center of the face of at least one second sample of the multiplicity of samples, with the distance having at least one of the following features:
(i) the distance corresponds to a diameter or a multiple of the diameter of the light beam;
(ii) the distance is less than 900 μm, less than 800 μm, less than 700 μm, less than 600 μm, less than 500 μm, less than 400 μm, less than 300 μm, less than 200 μm, less than 100 μm, less than 80 μm, less than 60 μm, less than 50 μm, less than 30 μm, less than 20 μm, or less than 10 μm, for example.

With regard to the possible definitions of the diameter of the light beam, reference is made to the comments further above, which also apply here.

No further sample of the multiplicity of samples is arranged between the first sample and the second sample. Expressed differently, the first sample and the second sample are arranged directly next to one another such that no further sample of the multiplicity of samples is arranged between the first sample and the second sample.

Deliberations have shown that a cylindrical sample is able to be obtained particularly well if the distance corresponds to the diameter or a multiple of the diameter of the light beam.

By way of example, the aforementioned distance is defined as set forth below. A first straight line, which is aligned perpendicular to the face of the first sample, runs through the center of the face of the first sample. Moreover, a second straight line, which is aligned perpendicular to the face of the second sample, runs through the center of the face of the second sample. The distance between the first sample and the second sample is the distance between the first straight line and the second straight line. By way of example, the distance is the length of a straight distance line, which intersects both the first straight line and the second straight line perpendicularly. As an alternative thereto, the distance is for example the minimum distance between the first straight line and the second straight line. What is stated above may also be expressed, for example, as follows: The distance between the first sample and the second sample is less than 30 μm, less than 20 μm, or less than 10 μm. By way of example, the first sample has a first edge. Further, the second sample has a second edge. The distance between the first sample and the second sample is the distance between the first edge and the second edge. By way of example, the distance is the length of a straight distance line, which runs from a first point on the first edge to a second point on the second edge. In particular, the distance is for example the minimum distance between the first edge and the second edge.

In even a further embodiment of the system described herein, provision is additionally or alternatively made for a respective marking to be arranged on the face of each sample of the multiplicity of samples. By way of example, the marking is arranged on the face of each of the samples of the multiplicity of samples using the light beam and/or the particle beam. The markings on the faces of the samples of the multiplicity of samples serve to render the individual samples uniquely identifiable.

In an embodiment of the system described herein, provision is additionally or alternatively made for the first direction to be changed into the second direction by rotating the first line in a plane. Additionally or as an alternative, provision is made for the first direction to be changed into the second direction by rotating the first line in a first plane and by rotating the first line in a second plane. Further additionally or as a further alternative, provision is made for the first line to run from a first point on the surface of the object in the direction of a second point on the surface of the object, with the axis of rotation intersecting the first line.

In a further embodiment of the system described herein, provision is additionally or alternatively made for the axis of rotation to be a first axis of rotation. Further, this embodiment of the system described herein provides for the second direction to be changed into a third direction. In this case, provision is made for the second direction to be changed into the third direction by rotating the second line about a second axis of rotation on the surface of the object. The second direction and the third direction differ from one another.

Then, the light beam is guided over the surface of the object in the third direction along a third line. Once again, material of the object is ablated when the light beam is guided over the surface of the object along the third line. Consequently, the light beam interacts with the material of the object while the light beam is guided along the third line. On account of the interaction of the light beam with the material of the object, material on the object is ablated such that the sample, or at least a part of the sample, is produced.

In yet a further embodiment of the system described herein, provision is additionally or alternatively made for the second direction to be changed into the third direction by rotating the second line in the plane. Additionally or as an alternative, provision is made for the second direction to be changed into the third direction by rotating the second line in the first plane and by rotating the second line in the second plane. Further additionally or as a further alternative, provision is made for the second line to run from a third point on the surface of the object in the direction of a fourth point on the surface of the object, with the second axis of rotation intersecting the second line. Further additionally or as a further alternative, provision is made for the third line to run from a fifth point on the surface of the object in the direction of a sixth point on the surface of the object.

In yet a further embodiment of the system described herein, provision is additionally or alternatively made for a scanning region to be determined on the object, with the scanning region including a multiplicity of scan lines. The light beam is guided along the multiplicity of scan lines. By way of example, the scan lines of the multiplicity of scan lines are arranged parallel to one another. By way of example, a scan line is in the form of a line. In particular, the first line, the second line, and/or the third line is/are part of the multiplicity of scan lines. By way of example, provision is made for the light beam to initially be guided along two or more scan lines, preferably along all scan lines, of the scanning region. In particular, the light beam is guided along a scan line from a first scan line end to a second scan line end of the scan line. Alternatively, the light beam is guided along the scan line from the second scan line end to the first scan line end of the scan line. However, the invention is not restricted to such a guidance of the light beam over the scan lines. Rather, any type of guidance over the scan lines which is suitable for the invention can be used in the invention. When the first direction is changed into the second direction, then the aforementioned scanning region rotates about the axis of rotation in this embodiment of the system described herein, and so all scan lines are also rotated. The rotation of the scanning region and the subsequent guidance of the light beam over the scan lines of the scanning region are repeated until the sample has been produced or the plurality of samples have been produced on the object.

In yet a further embodiment of the system described herein, provision is additionally or alternatively made for the light beam to be guided over the surface of the object in increments of less than 300 nm, less than 200 nm, or less than 100 nm.

In an embodiment of the system described herein, provision is additionally or alternatively made for the sample to be processed using a particle beam, with the particle beam being provided by a particle beam generator of the material processing device. Accordingly, this embodiment provides for production of the sample using the light beam to be followed by post-processing of the produced sample using the particle beam in order, where necessary, to bring the produced sample even closer to a cylindrical shape and/or to change the cylindrical form of the sample. By way of example, a tip is produced on the sample in this embodiment, in particular in order to enable examinations of the tip using atom probe tomography. With regard to atom probe tomography, reference is made to the comments made further above, which also apply here.

In a further embodiment of the system described herein, provision is additionally or alternatively made for a laser beam, more particularly a pulsed laser beam, to be used as a light beam, with the light beam device being designed as a laser beam device. By way of example, provision is made for a laser beam of an ultrashort pulse laser beam device to be used as light beam. In this context, both above and below, an ultrashort pulse laser beam device is understood to mean a laser beam device which provides a pulsed laser beam with pulse durations in the picosecond range or femtosecond range.

In yet a further embodiment of the system described herein, provision is additionally or alternatively made for a layer, for example a lacquer layer or an artificial resin layer, to be applied to the surface of the object. In particular, provision is made for the thickness of the layer to be substantially 10% to 20% of the height of the sample to be produced. In particular, provision is made for the layer to be applied in liquid form to the surface of the object. By way of example, the material of the layer is cured by the evaporation of a solvent contained in the material, by heating, and/or by irradiation with UV light over a certain period of time. In this embodiment of the system described herein, provision is now made for the previously applied layer to be removed again, for example using a solvent, after the sample is produced. It has been found that the cylindrical shape of the sample is obtainable particularly well using this embodiment of the system described herein. The aforementioned layer may also be applied using ion beam or electron beam deposition from a precursor gas of a gas injection system. However, this procedure is quite time-consuming on account of the size of the volumes to be applied.

None of the described embodiments of the invention are restricted to the aforementioned sequence of the explained steps. Rather, any sequence of the aforementioned steps suitable for the invention can be chosen for the invention.

The system described herein also relates to a computer program product that includes program code which is loadable or loaded into a processor of a material processing device, in particular of a particle beam apparatus, the program code, when executed in the processor, controlling the material processing device in such a way that a system having at least one of the features described herein or having a combination of at least two of the features described herein is carried out.

The system described herein also relates to a material processing device for processing an object. The material processing device according to the system described herein is not necessarily designed as a single apparatus. Rather, provision is made for the material processing device according to the system described herein to be designed as a system for example, the latter including a plurality of apparatuses and/or items of equipment, the plurality of apparatuses and/or items of equipment not necessarily needing to be arranged at one location. However, the plurality of apparatuses and/or items of equipment may be arranged at one location, for example. The material processing device according to the system described herein includes at least one light beam device that provides at least one light beam. Further, the material processing device according to the system described herein includes at least one guiding device for guiding the light beam. By way of example, the guiding device includes at least one mirror, at least one lens, a system of a plurality of mirrors, a system of a plurality of lenses, and/or a system of a plurality of mirrors and a plurality of lenses. Additionally or as an alternative, the material processing device according to the system described herein includes a movable object stage for arranging the object. The material processing device according to the system described herein also includes at least one control unit having a processor in which a computer program product having at least one of the features described herein or having a combination of at least two of the features described herein is loaded.

In an embodiment of the material processing device according to the system described herein, provision is additionally or alternatively made for the light beam device to be designed as a laser beam device. Accordingly, the light beam is embodied as a laser beam, more particularly as a pulsed laser beam. By way of example, provision is made for the light beam device to be designed as an ultrashort pulse laser beam device. As mentioned above, an ultrashort pulse laser beam device is understood to mean a laser beam device which provides a pulsed laser beam with pulse durations in the picosecond range or femtosecond range.

In a further embodiment of the material processing device according to the system described herein, provision is additionally or alternatively made for the material processing device according to the system described herein to have at least one particle beam apparatus that includes at least one beam generator that generates a particle beam with charged particles. The charged particles are electrons or ions, for example. Further, the particle beam apparatus includes at least one objective lens that focuses the particle beam on the object, at least one scanning device that scans the particle beam over the object, at least one detector that detects interaction particles and/or interaction radiation arising from an interaction of the particle beam with the object, and at least one display device that displays an image and/or an analysis of the object. By way of example, as a consequence of the interaction, in particular, particles are emitted by the object (so-called secondary particles, in particular secondary electrons) and particles of the particle beam are backscattered (so-called backscattered particles, in particular backscattered electrons). The secondary particles and backscattered particles are detected and used for image generation. An image representation of the object to be examined is thus obtained. Further, interaction radiation, for example x-ray radiation and cathodoluminescent light, is generated as a consequence of the interaction. In particular, the interaction radiation is used to analyze the object.

In yet a further embodiment of the material processing device according to the system described herein provision is additionally or alternatively made for the beam generator of the particle beam apparatus to be designed as a first beam generator and for the particle beam to be embodied as a first particle beam with first charged particles. Further, the objective lens of the particle beam apparatus is designed as a first objective lens for focusing the first particle beam on the object. Moreover, the particle beam apparatus of the material processing device according to the system described herein includes at least one second beam generator for generating a second particle beam that includes second charged particles. The second charged particles are ions or electrons, for example. Further, the particle beam apparatus includes at least one second objective lens for focusing the second particle beam onto the object.

In particular, provision is made for the material processing device to be designed as an electron beam apparatus and/or ion beam apparatus. Additionally or as an alternative, provision is made for the material processing device to be designed as the particle beam apparatus.

### BRIEF DESCRIPTION OF DRAWINGS

Further suitable or practical embodiments and advantages of the system described herein are described below in association with the drawings. In the figures:

FIG. 1 shows a schematic representation of a material processing device according to the system described herein;

FIG. 2 shows a first embodiment of a particle beam apparatus according to the system described herein;

FIG. 3 shows a second embodiment of a particle beam apparatus according to the system described herein;

FIG. 4 shows a third embodiment of a particle beam apparatus according to the system described herein;

FIG. 5 shows a schematic representation of a sample stage as a sample stage of a particle beam apparatus according to the system described herein;

FIG. 6 shows a further schematic representation of the sample stage according to FIG. 5;

FIG. 7 shows a schematic representation of a procedure of an embodiment according to the system described herein;

FIG. 8 shows a schematic representation of lines along which a light beam is guided according to the system described herein;

FIG. 9 shows a schematic representation of a scanning region on an object according to the system described herein;

FIG. 9A shows a further schematic representation of a scanning region on an object according to the system described herein;

FIG. 9B shows yet a further schematic representation of a scanning region on an object according to the system described herein;

FIG. 10 shows a schematic representation of an object of a multiplicity of samples according to the system described herein;

FIG. 11 shows a further step of an embodiment of a method according to the system described herein;

FIG. 12 shows a schematic representation of a multiplicity of samples according to the system described herein; and

FIG. 13 shows a further step of an embodiment of a method according to the system described herein.

### DETAILED DESCRIPTION OF VARIOUS EMBODIMENTS

The system is now described herein using a material processing device which is designed as a particle beam apparatus or which includes a particle beam apparatus. Particle beam apparatuses in the form of an SEM and in the form of a combination apparatus that include an electron beam column and an ion beam column are explained in more detail below. Express reference is made to the fact that the invention can be used in any particle beam apparatus, in particular in any electron beam apparatus and/or any ion beam apparatus.

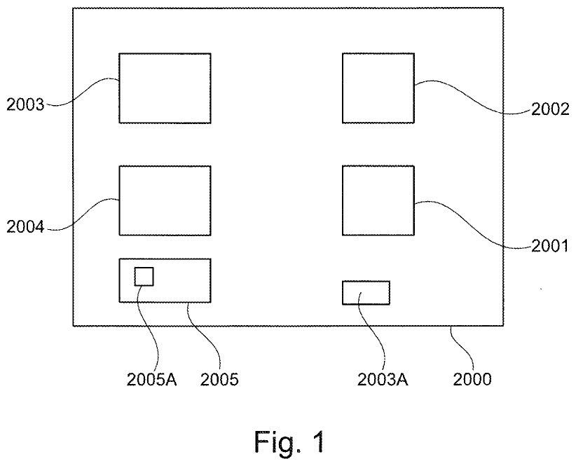

FIG. 1 shows a schematic representation of a material processing device 2000 according to an embodiment of the system described herein. The material processing device 2000 is provided for producing a sample or a multiplicity of samples on an object and includes a movably designed object stage 2001 for arranging the object. Moreover, the material processing device 2000 may include a determination device 2002 for determining a region of interest of the object. By way of example, the determination device 2002 is configured such that the position or the suspected position of a region of interest is able to be entered into the determination device 2002. Additionally or as an alternative, the determination device 2002 includes a device for non-destructive examination of the object for the purposes of determining a region of interest. In particular, provision is made for the determination device 2002 to include an x-ray beam device, an ultrasound device and/or a lock-in thermography device, to determine the region of interest. Expressed differently, the position of the region of interest in the object is determined using the aforementioned determination device 2002.

The material processing device 2000 also includes a light beam device 2003, which provides a light beam. By way of example, the light beam device 2003 is designed as a laser beam device. Accordingly, the light beam is embodied as a laser beam, more particularly as a pulsed laser beam. By way of example, provision is made for the light beam device 2003 to be designed as an ultrashort pulse laser beam device. As already mentioned above, an ultrashort pulse laser beam device is understood to mean a laser beam device which provides a pulsed laser beam with pulse durations in the picosecond range or femtosecond range.

The material processing device 2000 includes a guiding device 2003A for guiding the light beam. By way of example, the guiding device 2003A includes at least one mirror, at least one lens, a system of a plurality of mirrors, a system of a plurality of lenses, and/or a system of a plurality of mirrors and a plurality of lenses.

Moreover, the material processing device 2000 includes a particle beam apparatus 2004 with at least one beam generator for generating a particle beam with charged particles. The charged particles are electrons or ions, for example. Embodiments of the particle beam apparatus 2004 are explained in greater detail below.

The material processing device 2000 also includes a control device 2005 having a processor 2005A in which a computer program product is loaded, the latter, upon execution in the processor 2005A, controlling the material processing device 2000 in such a way that the system described herein is carried out. This is discussed in more detail below.

The material processing device 2000 is designed as, for example, an electron beam apparatus and/or an ion beam apparatus. Additionally or as an alternative, provision is made for the material processing device 2000 to be designed as the particle beam apparatus 2004. Expressed differently, the material processing device 2000 is formed by the particle beam apparatus 2004 itself. Further additionally or as a further alternative, the material processing device 2000 is designed for processing frozen, cooled, cold or vitrified objects. Expressed differently, the material processing device 2000 can be used within the scope of using cryo-technology.

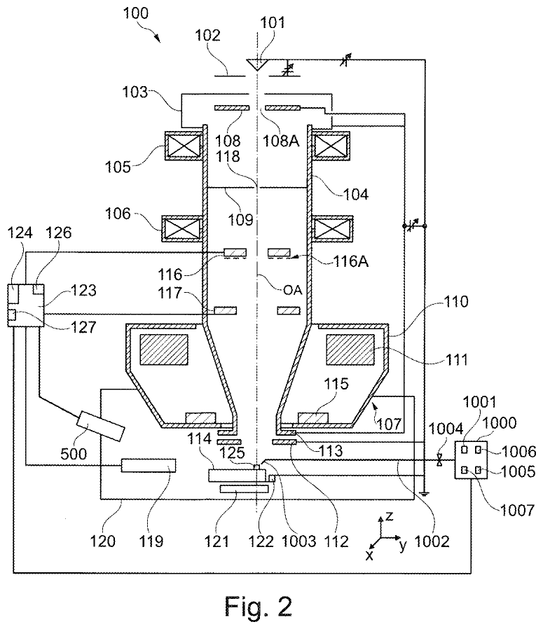

FIG. 2 shows a schematic representation of the particle beam apparatus 2004 in the form of an SEM 100. The SEM 100 includes a first beam generator in the form of an electron source 101, which is designed as a cathode. Further, the SEM 100 is provided with an extraction electrode 102 and with an anode 103, which is placed onto one end of a beam guiding tube 104 of the SEM 100. By way of example, the electron source 101 is designed as a thermal field emitter. However, the invention is not restricted to such an electron source 101. Rather, any electron source is utilizable.

Electrons emerging from the electron source 101 form a primary electron beam. The electrons are accelerated to the anode potential on account of a potential difference between the electron source 101 and the anode 103. In the embodiment depicted here, the anode potential is 100 V to 35 kV, for example 5 kV to 15 kV, in particular 8 kV, relative to a ground potential of a housing of a sample chamber 120. However, alternatively the anode potential could also be at ground potential.

Two condenser lenses, specifically a first condenser lens 105 and a second condenser lens 106, are arranged at the beam guiding tube 104. Proceeding from the electron source 101 as viewed in the direction of a first objective lens 107, the first condenser lens 105 is arranged first, followed by the second condenser lens 106. It is expressly pointed out that further embodiments of the SEM 100 can include only a single condenser lens. A first aperture unit 108 is arranged between the anode 103 and the first condenser lens 105. Together with the anode 103 and the beam guiding tube 104, the first aperture unit 108 is at a high voltage potential, specifically the potential of the anode 103, or connected to ground. The first aperture unit 108 has numerous first apertures 108A, of which one is depicted in FIG. 2. By way of example, two first apertures 108A are present. Each one of the numerous first apertures 108A has a different aperture diameter. Using an adjustment mechanism (not depicted), it is possible to set a desired first aperture 108A onto an optical axis OA of the SEM 100. Reference is explicitly made to the fact that, in further embodiments, the first aperture unit 108 may be provided with only a single aperture 108A. In an embodiment with a single aperture 108A, an adjustment mechanism can be absent. The first aperture unit 108 is then designed to be stationary. A stationary second aperture unit 109 is arranged between the first condenser lens 105 and the second condenser lens 106. As an alternative thereto, provision is made for the second aperture unit 109 to be designed to be movable.

The first objective lens 107 includes pole pieces 110, in which a hole is formed. The beam guiding tube 104 is guided through the hole. A coil 111 is arranged in the pole pieces 110.

An electrostatic retardation device is arranged in a lower region of the beam guiding tube 104 that includes an individual electrode 112 and a tube electrode 113. The tube electrode 113 is arranged at one end of the beam guiding tube 104 that faces an object 125 that is arranged on an object holder 114.

Together with the beam guiding tube 104, the tube electrode 113 is at the potential of the anode 103, while the individual electrode 112 and the object 125 are at a lower potential in relation to the potential of the anode 103. In the illustrated embodiment, the lower potential is the ground potential of the housing of the sample chamber 120. In this manner, the electrons of the primary electron beam can be decelerated to a desired energy which is required for examining the object 125.

The SEM 100 further includes a scanning device 115, that may deflect and scan the primary electron beam over the object 125. The electrons of the primary electron beam interact with the object 125. As a consequence of the interaction, interaction particles and/or interaction radiation arise/arises, which are/is detected. In particular, electrons are emitted from the surface of the object 125 or from regions of the object 125 close to the surface—so-called secondary electrons—or electrons of the primary electron beam are backscattered—so-called backscattered electrons—as interaction particles.

The object 125 and the individual electrode 112 can also be at different potentials and potentials different to ground. It is thereby possible to set the location of the retardation of the primary electron beam in relation to the object 125. By way of example, if the retardation is carried out quite close to the object 125, imaging aberrations become smaller.

A detector arrangement that includes a first detector 116 and a second detector 117 is arranged in the beam guiding tube 104 to detect the secondary electrons and/or the backscattered electrons. The first detector 116 is arranged on the source side along the optical axis OA, while the second detector 117 is arranged on the object side along the optical axis OA in the beam guiding tube 104. The first detector 116 and the second detector 117 are arranged offset from one another in the direction of the optical axis OA of the SEM 100. Both the first detector 116 and the second detector 117 have a respective passage opening, through which the primary electron beam can pass. The first detector 116 and the second detector 117 are approximately at the potential of the anode 103 and of the beam guiding tube 104. The optical axis OA of the SEM 100 runs through the respective passage openings.

The second detector 117 serves principally for detecting secondary electrons. Upon emerging from the object 125, the secondary electrons initially have a low kinetic energy and random directions of motion. Using the strong extraction field emanating from the tube electrode 113, the secondary electrons are accelerated in the direction of the first objective lens 107. The secondary electrons enter the first objective lens 107 approximately parallel. The beam diameter of the beam of the secondary electrons remains small in the first objective lens 107 as well. The first objective lens 107 then has a strong effect on the secondary electrons and generates a comparatively short focus of the secondary electrons with sufficiently steep angles with respect to the optical axis OA, such that the secondary electrons diverge far apart from one another downstream of the focus and strike the second detector 117 on the active area thereof. By contrast, only a small proportion of electrons that are backscattered at the object 125—that is to say backscattered electrons which have a relatively high kinetic energy in comparison with the secondary electrons upon emerging from the object 125—are detected by the second detector 117. The high kinetic energy and the angles of the backscattered electrons with respect to the optical axis OA upon emerging from the object 125 have the effect that a beam waist, that is to say a beam region having a minimum diameter, of the backscattered electrons lies in the vicinity of the second detector 117. A large portion of the backscattered electrons passes through the passage opening of the second detector 117. Therefore, the first detector 116 substantially serves to detect the backscattered electrons.

In a further embodiment of the SEM 100, the first detector 116 can additionally be designed with an opposing field grid 116A. The opposing field grid 116A is arranged at the side of the first detector 116 directed toward the object 125. With respect to the potential of the beam guiding tube 104, the opposing field grid 116A has a negative potential such that only backscattered electrons with a high energy pass through the opposing field grid 116A to the first detector 116. Additionally or as an alternative, the second detector 117 includes a further opposing field grid, which has an analogous embodiment to the aforementioned opposing field grid 116A of the first detector 116 and which has an analogous function.

Further, the SEM 100 includes in the sample chamber 120 a chamber detector 119, for example an Everhart-Thornley detector or an ion detector, which has a detection surface that is coated with metal and blocks light.

The detection signals generated by the first detector 116, the second detector 117, and the chamber detector 119 are used to generate an image or images of the surface of the object 125.

It is expressly pointed out that the apertures of the first aperture unit 108 and of the second aperture unit 109, as well as the passage openings of the first detector 116 and of the second detector 117, are depicted in exaggerated fashion. The passage openings of the first detector 116 and of the second detector 117 have an extent perpendicular to the optical axis OA in the range of 0.5 mm to 5 mm. By way of example, the passage openings are of circular design and have a diameter in the range of 1 mm to 3 mm perpendicular to the optical axis OA.

The second aperture unit 109 is configured as a pinhole aperture unit in the embodiment depicted in FIG. 2 and is provided with a second aperture 118 for the passage of the primary electron beam, which has an extent in the range from 5 μm to 500 μm, for example 35 μm. As an alternative thereto, provision is made in a further embodiment for the second aperture unit 109 to be provided with a plurality of apertures, which can be displaced mechanically with respect to the primary electron beam or which can be reached by the primary electron beam by the use of electrical and/or magnetic deflection elements. The second aperture unit 109 is designed as a pressure stage aperture unit that separates a first region, in which the electron source 101 is arranged and in which there is an ultra-high vacuum (10⁻⁷ hPa to 10⁻¹² hPa), from a second region, which has a high vacuum (10⁻³ hPa to 10⁻⁷ hPa). The second region is the intermediate pressure region of the beam guiding tube 104, which leads to the sample chamber 120.

The sample chamber 120 is under vacuum. For the purposes of producing the vacuum, a pump (not depicted) is arranged at the sample chamber 120. In the embodiment depicted in FIG. 2, the sample chamber 120 is operated in a first pressure range or in a second pressure range. The first pressure range includes only pressures of less than or equal to 10⁻³ hPa, and the second pressure range includes only pressures of greater than 10⁻³ hPa. To ensure the pressure ranges, the sample chamber 120 is vacuum-sealed.

The object holder 114 is arranged at a sample stage 122. By way of example, the sample stage 122 is designed as the object stage 2001 of the material processing device 2000. The sample stage 122 has movement units such that the object holder 114 is designed to be movable in three directions arranged perpendicular to one another, specifically in an x-direction (first stage axis), in a y-direction (second stage axis), and in a z-direction (third stage axis). Moreover, the sample stage 122 has movement units such that the object holder 114 can be rotated about two axes of rotation (stage axes of rotation) arranged perpendicular to one another. The invention is not restricted to the sample stage 122 described above. Rather, the sample stage 122 can have further translation axes and axes of rotation along which or about which the object holder 114 can move.

The SEM 100 further includes a third detector 121, which is arranged in the sample chamber 120. More precisely, the third detector 121 is arranged downstream of the sample stage 122, as viewed from the electron source 101 along the optical axis OA. The sample stage 122, and hence the object holder 114, can be rotated in such a way that the primary electron beam can radiate through the object 125 arranged on the object holder 114. When the primary electron beam passes through the object 125 to be examined, the electrons of the primary electron beam interact with the material of the object 125 to be examined. The electrons passing through the object 125 to be examined are detected by the third detector 121.

Arranged at the sample chamber 120 is a radiation detector 500, which is used to detect interaction radiation, for example x-ray radiation and/or cathodoluminescent light. The radiation detector 500, the first detector 116, the second detector 117, and the chamber detector 119 are connected to a control unit 123, which includes a monitor 124. The third detector 121 is also connected to the control unit 123, which is not depicted for reasons of clarity. The control unit 123 processes detection signals that are generated by the first detector 116, the second detector 117, the chamber detector 119, the third detector 121, and/or the radiation detector 500 and displays the detection signals in the form of images or spectra on the monitor 124.

The control unit 123 furthermore has a database 126, in which data are stored and from which data are read out. By way of example, the control unit 123 is designed as the control device 2005 of the material processing device 2000. The control unit 123 includes a processor 127, which for example is designed as the processor 2005A and/or in which a computer program product with program code is loaded which, upon execution, controls the material processing device 2000 and/or the SEM 100 in such a way that the system described herein is carried out. This is discussed in more detail below.

The SEM 100 includes a gas feed device 1000, which serves to feed a gaseous precursor to a specific position on the surface of the object 125. The gas feed device 1000 includes a gas reservoir in the form of a precursor reservoir 1001. By way of example, the precursor is received as a solid, gaseous or liquid substance in the precursor reservoir 1001. By heating and/or cooling the precursor, the equilibrium between the solid phase, the liquid phase, and the gaseous phase is adjusted in such a way that the required vapor pressure is available. By way of example, phenanthrene is used as precursor. Essentially a layer of carbon or a carbon-containing layer then deposits on the surface of the object 125. As an alternative thereto, by way of example, a precursor that includes metal can be used to deposit a metal or a metal-containing layer on the surface of the object 125. However, the depositions are not limited to carbon and/or metals. Rather, any substances can be deposited on the surface of the object 125, for example semiconductors, non-conductors or other compounds. Furthermore, provision is also made for the precursor to be used for removing material of the object 125 upon interaction with the particle beam.

The gas feed device 1000 is provided with a feed line 1002. The feed line 1002 has, in the direction of the object 125, an acicular hollow tube 1003, which is able to be brought into the vicinity of the surface of the object 125, for example at a distance of 10 μm to 1 mm from the surface of the object 125. The hollow tube 1003 has a feed opening, the diameter of which is for example in the range of 10 μm to 1000 μm, in particular in the range of 100 μm to 600 μm. The feed line 1002 has a valve 1004 in order to regulate the flow rate of gaseous precursor into the feed line 1002. Expressed differently, when the valve 1004 is opened, gaseous precursor from the precursor reservoir 1001 is introduced into the feed line 1002 and guided via the hollow tube 1003 to the surface of the object 125. When the valve 1004 is closed, the flow of the gaseous precursor onto the surface of the object 125 is stopped.

The gas feed device 1000 is furthermore provided with an adjusting unit 1005, which enables an adjustment of the position of the hollow tube 1003 in all 3 spatial directions—namely an x-direction, a y-direction, and a z-direction—and an adjustment of the orientation of the hollow tube 1003 using a rotation and/or a tilt. The gas feed device 1000 and thus also the adjusting unit 1005 are connected to the control unit 123 of the SEM 100.

In further embodiments, the precursor reservoir 1001 is not arranged directly at the gas feed device 1000. Rather, in further embodiments, provision is made for the precursor reservoir 1001 to be arranged, for example, at a wall of a space in which the SEM 100 is situated.

The gas feed device 1000 includes a temperature measuring unit 1006. By way of example, an infrared measuring apparatus or a semiconductor temperature sensor is used as temperature measuring unit 1006. However, the invention is not restricted to the use of such temperature measuring units. Rather, any suitable temperature measuring unit which is suitable for the invention can be used as temperature measuring unit. In particular, provision can be made for the temperature measuring unit 1006 not to be arranged at the gas feed device 1000, but rather, to be arranged for example at a distance from the gas feed device 1000.

The gas feed device 1000 further includes a temperature setting unit 1007. By way of example, the temperature setting unit 1007 is a heating device, in particular a conventional infrared heating device. As an alternative, the temperature setting unit 1007 is designed as a heating and/or cooling device, which includes a heating wire and/or a Peltier element, for example. However, the invention is not restricted to the use of such a temperature setting unit 1007. Rather, any suitable temperature setting unit can be used for the invention.

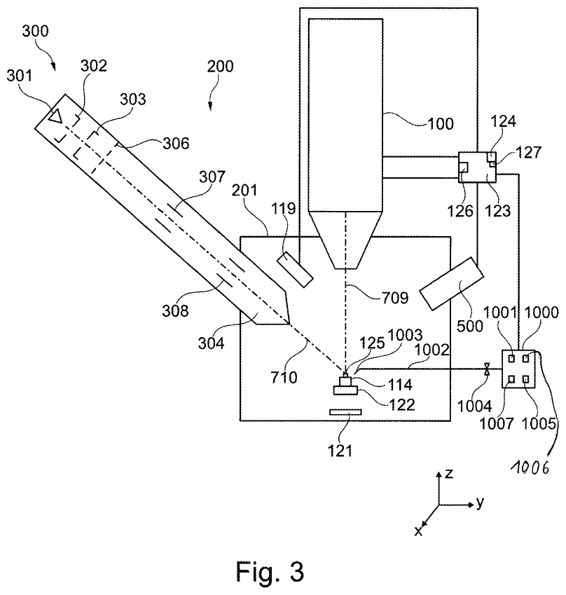

FIG. 3 shows a schematic representation of the particle beam apparatus 2004 in the form of a combination apparatus 200. The combination apparatus 200 includes two particle beam columns. Firstly, the combination apparatus 200 is provided with the SEM 100, as already depicted in FIG. 2, but without the sample chamber 120. Rather, the SEM 100 is arranged at a sample chamber 201. The sample chamber 201 is under vacuum. For the purposes of producing the vacuum, a pump (not depicted) is arranged at the sample chamber 201. In the embodiment depicted in FIG. 3, the sample chamber 201 is operated in a first pressure range or in a second pressure range. The first pressure range includes only pressures of less than or equal to 10⁻³ hPa, and the second pressure range includes only pressures of greater than 10⁻³ hPa. To ensure the pressure ranges, the sample chamber 201 is vacuum-sealed.

Arranged in the sample chamber 201 is the chamber detector 119 which is designed, for example, in the form of an Everhart-Thornley detector or an ion detector and which has a detection surface coated with metal that blocks light. Further, the third detector 121 is arranged in the sample chamber 201.

The SEM 100 serves to generate a first particle beam, specifically the primary electron beam already described further above, and has the optical axis, already specified above, which is provided with the reference sign 709 in FIG. 3 and which is also referred to as first beam axis below. Secondly, the combination apparatus 200 is provided with an ion beam apparatus 300, which is likewise arranged at the sample chamber 201. The ion beam apparatus 300 likewise has an optical axis, which is provided with the reference sign 710 in FIG. 3 and which is also referred to as second beam axis below.

The SEM 100 is arranged vertically in relation to the sample chamber 201. By contrast, the ion beam apparatus 300 is arranged in a manner inclined by an angle of approximately 0° to 90° in relation to the SEM 100. An arrangement of approximately 50° is depicted by way of example in FIG. 3. The ion beam apparatus 300 includes a second beam generator in the form of an ion beam generator 301. Ions, which form a second particle beam in the form of an ion beam, are generated by the ion beam generator 301. The ions are accelerated using an extraction electrode 302, which is at a predefinable potential. The second particle beam then passes through an ion optical unit of the ion beam apparatus 300, where the ion optical unit includes a condenser lens 303 and a second objective lens 304. The second objective lens 304 ultimately generates an ion probe, which is focused onto the object 125 arranged at an object holder 114. The object holder 114 is arranged at a sample stage 122. By way of example, the sample stage 122 is designed as the object stage 2001 of the material processing device 2000.

An adjustable or selectable aperture unit 306, a first electrode arrangement 307, and a second electrode arrangement 308 are arranged above the second objective lens 304 (i.e., in the direction of the ion beam generator 301), with the first electrode arrangement 307 and the second electrode arrangement 308 being designed as scanning electrodes. The second particle beam is scanned over the surface of the object 125 using the first electrode arrangement 307 and the second electrode arrangement 308, with the first electrode arrangement 307 acting in a first direction and the second electrode arrangement 308 acting in a second direction, which is counter to the first direction. Thus, scanning is carried out in an x-direction, for example. The scanning in a y-direction perpendicular thereto is brought about by further electrodes (not depicted), which are rotated by 90°, at the first electrode arrangement 307 and at the second electrode arrangement 308.

As explained above, the object holder 114 is arranged at the sample stage 122. In the embodiment shown in FIG. 3, too, the sample stage 122 has movement units such that the object holder 114 is designed to be movable in three directions arranged perpendicular to one another, specifically in an x-direction (first stage axis), in a y-direction (second stage axis), and in a z-direction (third stage axis). Moreover, the sample stage 122 has movement units such that the object holder 114 can be rotated about two axes of rotation (stage axes of rotation) arranged perpendicular to one another.

The distances depicted in FIG. 3 between the individual units of the combination apparatus 200 are depicted in exaggerated fashion in order to better illustrate the individual units of the combination apparatus 200.

Arranged at the sample chamber 201 is a radiation detector 500, which is used to detect interaction radiation, for example, x-ray radiation and/or cathodoluminescent light. The radiation detector 500 is connected to a control unit 123, which includes a monitor 124. By way of example, the control unit 123 is designed as the control device 2005 of the material processing device 2000.

The control unit 123 processes detection signals that are generated by the first detector 116, the second detector 117 (not depicted in FIG. 3), the chamber detector 119, the third detector 121, and/or the radiation detector 500 and displays the detection signals in the form of images or spectra on the monitor 124.

The control unit 123 furthermore has a database 126, in which data are stored and from which data are read out. Moreover, the control unit 123 includes a processor 127, which for example is designed as the processor 2005A and/or in which a computer program product with program code is loaded which, upon execution, controls the material processing device 2000 and/or the combination apparatus 200 in such a way that the system described herein is carried out. This is discussed in more detail below.

The combination apparatus 200 includes a gas feed device 1000, which serves to feed a gaseous precursor to a specific position on the surface of the object 125. The gas feed device 1000 includes a gas reservoir in the form of a precursor reservoir 1001. By way of example, the precursor is received as a solid, gaseous or liquid substance in the precursor reservoir 1001. By heating and/or cooling the precursor, the equilibrium between the solid phase, the liquid phase, and the gaseous phase is adjusted in such a way that the required vapor pressure is available.

By way of example, phenanthrene is used as precursor. Essentially a layer of carbon or a carbon-containing layer then deposits on the surface of the object 125. As an alternative thereto, by way of example, a precursor including metal can be used to deposit a metal or a metal-containing layer on the surface of the object 125. However, the depositions are not limited to carbon and/or metals. Rather, any substances can be deposited on the surface of the object 125, for example semiconductors, non-conductors or other compounds. Furthermore, provision is also made for the precursor to be used for removing material of the object 125 upon interaction with one of the two particle beams.

The gas feed device 1000 is provided with a feed line 1002. The feed line 1002 has, in the direction of the object 125, an acicular hollow tube 1003, which is able to be brought into the vicinity of the surface of the object 125, for example at a distance of 10 μm to 1 mm from the surface of the object 125. The hollow tube 1003 has a feed opening, the diameter of which is for example in the range of 10 μm to 1000 μm, in particular in the range of 100 μm to 600 μm. The feed line 1002 has a valve 1004 in order to regulate the flow rate of gaseous precursor into the feed line 1002. Expressed differently, when the valve 1004 is opened, gaseous precursor from the precursor reservoir 1001 is introduced into the feed line 1002 and guided via the hollow tube 1003 to the surface of the object 125. When the valve 1004 is closed, the flow of the gaseous precursor onto the surface of the object 125 is stopped.

The gas feed device 1000 is furthermore provided with an adjusting unit 1005, which enables an adjustment of the position of the hollow tube 1003 in all 3 spatial directions—namely an x-direction, a y-direction, and a z-direction—and an adjustment of the orientation of the hollow tube 1003 using a rotation and/or a tilt. The gas feed device 1000 and thus also the adjusting unit 1005 are connected to the control unit 123 of the combination apparatus 200.

In further embodiments, the precursor reservoir 1001 is not arranged directly at the gas feed device 1000. Rather, in further embodiments, provision is made for the precursor reservoir 1001 to be arranged for example at a wall of a space in which the combination apparatus 200 is situated.

The gas feed device 1000 includes a temperature measuring unit 1006. By way of example, an infrared measuring apparatus or a semiconductor temperature sensor is used as temperature measuring unit 1006. However, the invention is not restricted to the use of such temperature measuring units. Rather, any suitable temperature measuring unit which is suitable for the invention can be used as temperature measuring unit. In particular, provision can be made for the temperature measuring unit 1006 not to be arranged at the gas feed device 1000 itself, but rather to be arranged, for example, at a distance from the gas feed device 1000.

The gas feed device 1000 further includes a temperature setting unit 1007. By way of example, the temperature setting unit 1007 is a heating device, in particular a conventional infrared heating device. As an alternative, the temperature setting unit 1007 is designed as a heating and/or cooling device, which includes a heating wire and/or a Peltier element, for example. However, the invention is not restricted to the use of such a temperature setting unit 1007. Rather, any suitable temperature setting unit can be used for the invention.

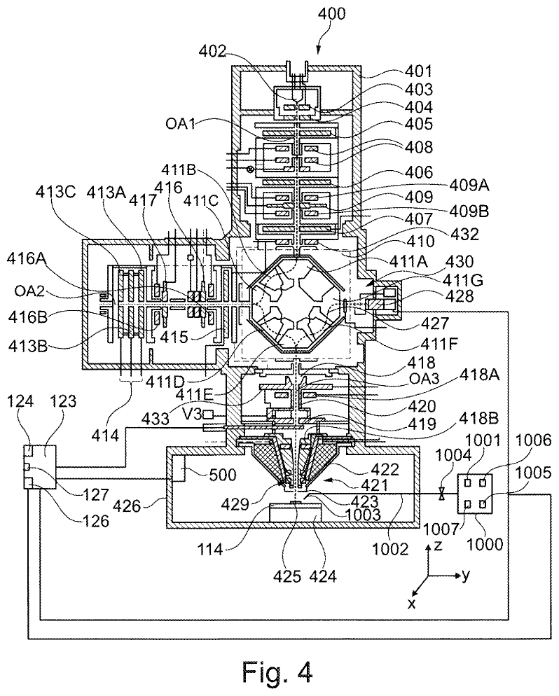

FIG. 4 shows a schematic representation of the particle beam apparatus 2004 in the form of a further particle beam apparatus. This embodiment of the particle beam apparatus is provided with the reference sign 400 and includes a mirror corrector for correcting chromatic and/or spherical aberrations, for example. The particle beam apparatus 400 includes a particle beam column 401, which is designed as an electron beam column and which substantially corresponds to an electron beam column of a corrected SEM. However, the particle beam apparatus 400 is not restricted to an SEM with a mirror corrector. Rather, the particle beam apparatus 400 may include any type of corrector units.

The particle beam column 401 includes a particle beam generator in the form of an electron source 402 (cathode), an extraction electrode 403, and an anode 404. By way of example, the electron source 402 is designed as a thermal field emitter. Electrons emerging from the electron source 402 are accelerated to the anode 404 on account of a potential difference between the electron source 402 and the anode 404. Accordingly, a particle beam in the form of an electron beam is formed along a first optical axis OA1.

The particle beam is guided along a beam path, which corresponds to the first optical axis OA1, after the particle beam has emerged from the electron source 402. A first electrostatic lens 405, a second electrostatic lens 406, and a third electrostatic lens 407 are used to guide the particle beam.

Furthermore, the particle beam is set along the beam path using a beam guiding device. The beam guiding device of the embodiment of FIG. 4 includes a source setting unit with two magnetic deflection units 408 arranged along the first optical axis OA1. Moreover, the particle beam apparatus 400 includes electrostatic beam deflection units. A first electrostatic beam deflection unit 409, which is also designed as a quadrupole in a further embodiment, is arranged between the second electrostatic lens 406 and the third electrostatic lens 407. The first electrostatic beam deflection unit 409 is likewise arranged downstream of the magnetic deflection units 408. A first multi-pole unit 409A in the form of a first magnetic deflection unit is arranged at one side of the first electrostatic beam deflection unit 409. Moreover, a second multi-pole unit 409B in the form of a second magnetic deflection unit is arranged at the other side of the first electrostatic beam deflection unit 409. The first electrostatic beam deflection unit 409, the first multi-pole unit 409A, and the second multi-pole unit 409B are set for the purposes of setting the particle beam in respect of the axis of the third electrostatic lens 407 and the entrance window of a beam deflection device 410. The first electrostatic beam deflection unit 409, the first multi-pole unit 409A, and the second multi-pole unit 409B can interact like a Wien filter. A further magnetic deflection element 432 is arranged at the entrance to the beam deflection device 410.

The beam deflection device 410 is used as a particle beam deflector, which deflects the particle beam in a specific manner. The beam deflection device 410 includes a plurality of magnetic sectors, specifically a first magnetic sector 411A, a second magnetic sector 411B, a third magnetic sector 411C, a fourth magnetic sector 411D, a fifth magnetic sector 411E, a sixth magnetic sector 411F, and a seventh magnetic sector 411G. The particle beam enters the beam deflection device 410 along the first optical axis OA1 and the particle beam is deflected by the beam deflection device 410 in the direction of a second optical axis OA2. The beam deflection is performed using the first magnetic sector 411A, using the second magnetic sector 411B, and using the third magnetic sector 411C through an angle of 30° to 120° . The second optical axis OA2 is oriented at the same angle with respect to the first optical axis OA1. The beam deflection device 410 also deflects the particle beam which is guided along the second optical axis OA2, to be precise in the direction of a third optical axis 0A3. The beam deflection is provided by the third magnetic sector 411C, the fourth magnetic sector 411D, and the fifth magnetic sector 411E. In the embodiment in FIG. 4, the deflection with respect to the second optical axis OA2 and with respect to the third optical axis OA3 is provided by deflection of the particle beam at an angle of 90°. Hence, the third optical axis OA3 runs coaxially with respect to the first optical axis OA1. However, it is pointed out that the particle beam apparatus 400 according to the invention described here is not restricted to deflection angles of 90°. Rather, any suitable deflection angle can be selected by the beam deflection device 410, for example 70° or 110°, such that the first optical axis OA1 does not run coaxially with respect to the third optical axis OA3. In respect of further details of the beam deflection device 410, reference is made to WO 02/067286 A2.

After the particle beam has been deflected by the first magnetic sector 411A, the second magnetic sector 411B, and the third magnetic sector 411C, the particle beam is guided along the second optical axis OA2. The particle beam is guided to an electrostatic mirror 414 and travels on a path to the electrostatic mirror 414 along a fourth electrostatic lens 415, a third multi-pole unit 416A in the form of a magnetic deflection unit, a second electrostatic beam deflection unit 416, a third electrostatic beam deflection unit 417, and a fourth multi-pole unit 416B in the form of a magnetic deflection unit. The electrostatic mirror 414 includes a first mirror electrode 413A, a second mirror electrode 413B, and a third mirror electrode 413C. Electrons of the particle beam which are reflected back at the electrostatic mirror 414 once again travel along the second optical axis OA2 and re-enter the beam deflection device 410. Then, the electrons are deflected to the third optical axis OA3 by the third magnetic sector 411C, the fourth magnetic sector 411D, and the fifth magnetic sector 411E.

The electrons of the particle beam emerge from the beam deflection device 410 and the electrons are guided along the third optical axis OA3 to an object 425 that is intended to be examined and is arranged in an object holder 114.

On the path to the object 425, the particle beam is guided to a fifth electrostatic lens 418, a beam guiding tube 420, a fifth multi-pole unit 418A, a sixth multi-pole unit 418B, and an objective lens 421. The fifth electrostatic lens 418 is an electrostatic immersion lens. Using the fifth electrostatic lens 418, the particle beam is braked or accelerated to an electric potential of the beam guiding tube 420.

Using the objective lens 421, the particle beam is focused into a focal plane in which the object 425 is arranged. The object holder 114 is arranged at a movable sample stage 424. By way of example, the sample stage 424 is designed as the object stage 2001 of the material processing device 2000. The movable sample stage 424 is arranged in a sample chamber 426 of the particle beam apparatus 400. The sample stage 424 has movement units such that the object holder 114 is designed to be movable in three directions arranged perpendicular to one another, specifically in an x-direction (first stage axis), in a y-direction (second stage axis), and in a z-direction (third stage axis). Moreover, the sample stage 424 has movement units such that the object holder 114 can be rotated about two axes of rotation (stage axes of rotation) arranged perpendicular to one another.

The sample chamber 426 is under vacuum. For the purposes of producing the vacuum, a pump (not depicted) is arranged at the sample chamber 426. In the embodiment depicted in FIG. 4, the sample chamber 426 is operated in a first pressure range or in a second pressure range. The first pressure range includes only pressures of less than or equal to 10⁻³ hPa, and the second pressure range includes only pressures of greater than 10⁻³ hPa. To ensure the pressure ranges, the sample chamber 426 is vacuum-sealed.

The objective lens 421 can be designed as a combination of a magnetic lens 422 and a sixth electrostatic lens 423. The end of the beam guiding tube 420 can furthermore be an electrode of an electrostatic lens. After emerging from the beam guiding tube 420, particles of the particle beam apparatus are decelerated to a potential of the object 425. The objective lens 421 is not restricted to a combination of the magnetic lens 422 and the sixth electrostatic lens 423. Rather, the objective lens 421 may assume any suitable embodiment. By way of example, the objective lens 421 can also be designed as a purely magnetic lens or as a purely electrostatic lens.

The particle beam which is focused onto the object 425 interacts with the object 425. Interaction particles are generated. In particular, secondary electrons are emitted from the object 425 or backscattered electrons are backscattered at the object 425. The secondary electrons or the backscattered electrons are accelerated again and guided into the beam guiding tube 420 along the third optical axis OA3. In particular, the trajectories of the secondary electrons and the backscattered electrons extend on the route of the beam path of the particle beam in the opposite direction to the particle beam.

The particle beam apparatus 400 includes a first analysis detector 419, which is arranged between the beam deflection device 410 and the objective lens 421 along the beam path. Secondary electrons travelling in directions oriented at a large angle with respect to the third optical axis 0A3 are detected by the first analysis detector 419. Backscattered electrons and secondary electrons which have a small axial distance with respect to the third optical axis 0A3 at the location of the first analysis detector 419—i.e., backscattered electrons and secondary electrons which have a small distance from the third optical axis OA3 at the location of the first analysis detector 419—enter the beam deflection device 410 and are deflected to a second analysis detector 428 by the fifth magnetic sector 411E, the sixth magnetic sector 411F, and the seventh magnetic sector 411G along a detection beam path 427. By way of example, the deflection angle is 90° or 110°.

The first analysis detector 419 generates detection signals which are largely generated by emitted secondary electrons. The detection signals which are generated by the first analysis detector 419 are guided to a control unit 123 and are used to obtain information about the properties of the interaction region of the focused particle beam with the object 425. In particular, the focused particle beam is scanned over the object 425 using a scanning device 429. Using the detection signals generated by the first analysis detector 419, an image of the scanned region of the object 425 can then be generated and displayed on a display unit. The display unit is, for example, a monitor 124 that is arranged at the control unit 123. By way of example, the control unit 123 is designed as the control device 2005 of the material processing device 2000.

The second analysis detector 428 is also connected to the control unit 123. Detection signals of the second analysis detector 428 are passed to the control unit 123 and used to generate an image of the scanned region of the object 425 and to display it on a display unit. The display unit is for example the monitor 124 that is arranged at the control unit 123.

Arranged at the sample chamber 426 is a radiation detector 500, which is used to detect interaction radiation, for example x-ray radiation and/or cathodoluminescent light. The radiation detector 500 is connected to the control unit 123, which includes the monitor 124. The control unit 123 processes detection signals of the radiation detector 500 and displays the signals in the form of images and/or spectra on the monitor 124.

The control unit 123 furthermore has a database 126, in which data are stored and from which data are read out. Moreover, the control unit 123 includes a processor 127, which, for example, is designed as the processor 2005A and/or in which a computer program product with program code is loaded which, upon execution, controls the material processing device 2000 and/or the particle beam apparatus 400 in such a way that the system described herein is carried out. This is discussed in more detail below.

The particle beam apparatus 400 includes a gas feed device 1000, which serves to feed a gaseous precursor to a specific position on the surface of the object 425. The gas feed device 1000 includes a gas reservoir in the form of a precursor reservoir 1001. By way of example, the precursor is received as a solid, gaseous or liquid substance in the precursor reservoir 1001. By heating and/or cooling the precursor, the equilibrium between the solid phase, the liquid phase, and the gaseous phase is adjusted in such a way that the required vapor pressure is available.

By way of example, phenanthrene is used as a precursor. Essentially a layer of carbon or a carbon-containing layer then deposits on the surface of the object 425. As an alternative thereto, by way of example, a precursor including metal can be used to deposit a metal or a metal-containing layer on the surface of the object 425. However, the depositions are not limited to carbon and/or metals. Rather, any substances can be deposited on the surface of the object 425, for example semiconductors, non-conductors or other compounds. Furthermore, provision is also made for the precursor to be used for removing material of the object 425 upon interaction with a particle beam.

The gas feed device 1000 is provided with a feed line 1002. The feed line 1002 has, in the direction of the object 425, an acicular hollow tube 1003, which is able to be brought into the vicinity of the surface of the object 425, for example at a distance of 10 μm to 1 mm from the surface of the object 425. The hollow tube 1003 has a feed opening, the diameter of which is, for example, in the range of 10 μm to 1000 μm, in particular in the range of 100 μm to 600 μm. The feed line 1002 has a valve 1004 in order to regulate the flow rate of gaseous precursor into the feed line 1002. Expressed differently, when the valve 1004 is opened, gaseous precursor from the precursor reservoir 1001 is introduced into the feed line 1002 and guided via the hollow tube 1003 to the surface of the object 425. When the valve 1004 is closed, the flow of the gaseous precursor onto the surface of the object 425 is stopped.

The gas feed device 1000 is furthermore provided with an adjusting unit 1005, which enables an adjustment of the position of the hollow tube 1003 in all 3 spatial directions—namely an x-direction, a y-direction, and a z-direction—and an adjustment of the orientation of the hollow tube 1003 using a rotation and/or a tilting. The gas feed device 1000 and thus also the adjusting unit 1005 are connected to the control unit 123 of the particle beam apparatus 400.

In further embodiments, the precursor reservoir 1001 is not arranged directly at the gas feed device 1000. Rather, in further embodiments, provision is made for the precursor reservoir 1001 to be arranged for example at a wall of a space in which the particle beam apparatus 400 is situated.

The gas feed device 1000 includes a temperature measuring unit 1006. By way of example, an infrared measuring apparatus or a semiconductor temperature sensor is used as the temperature measuring unit 1006. However, the invention is not restricted to the use of such temperature measuring units. Rather, any suitable temperature measuring unit which is suitable for the invention can be used as temperature measuring unit. In particular, provision can be made for the temperature measuring unit 1006 not to be arranged at the gas feed device 1000 itself, but rather to be arranged for example at a distance from the gas feed device 1000.

The gas feed device 1000 further includes a temperature setting unit 1007. By way of example, the temperature setting unit 1007 is a heating device, in particular a conventional infrared heating device. As an alternative, the temperature setting unit 1007 is designed as a heating and/or cooling device, which includes a heating wire and/or a Peltier element, for example. However, the invention is not restricted to the use of such a temperature setting unit 1007. Rather, any suitable temperature setting unit can be used for the invention.

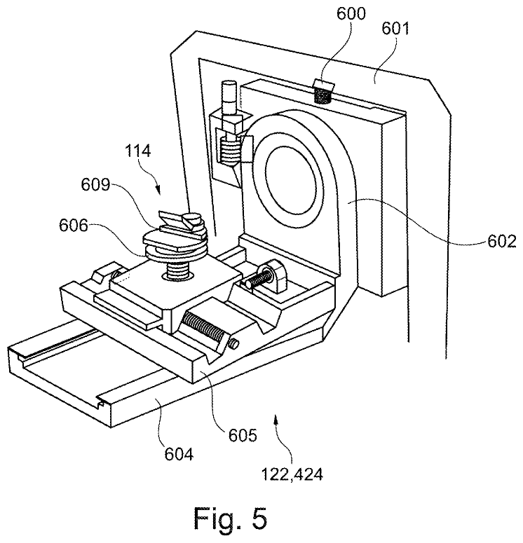

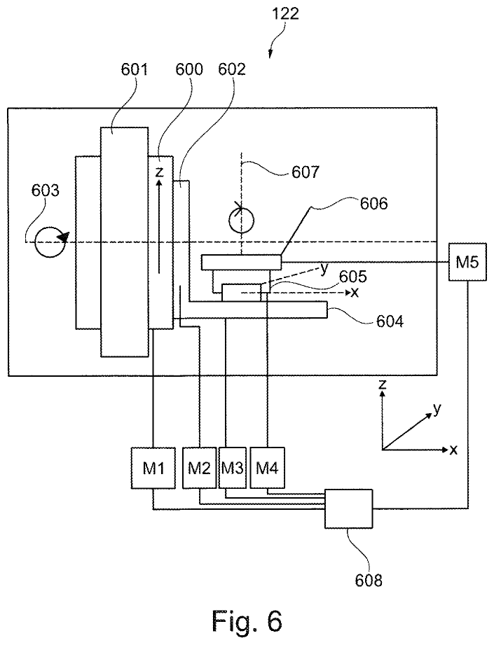

The sample stage 122 of the SEM 100, the sample stage 122 of the combination apparatus 200, and the sample stage 424 of the particle beam apparatus 400 are discussed below. The sample stages 122, 424 are designed as a sample stage with movement units, which is depicted schematically in FIGS. 5 and 6. Reference is made to the fact that the invention is not restricted to the sample stage 122, 424 described here. Rather, the invention can have any movable sample stage that is suitable for the invention.

Arranged on the sample stage 122, 424 is the object holder 114 with the object 125, 425. The sample stage 122, 424 has movement units that ensure a movement of the object holder 114 in such a way that a region of interest on the object 125, 425 can be examined and/or processed using a particle beam. The movement units are depicted schematically in FIGS. 5 and 6 and are explained below.

The sample stage 122, 424 has a first movement unit 600 on a housing 601 of the sample chamber 120, 201, 426, in which the sample stage 122, 424 is arranged. The first movement unit 600 enables a movement of the object holder 114 along the z-axis (third stage axis). Further, provision is made of a second movement unit 602. The second movement unit 602 enables a rotation of the object holder 114 about a first stage axis of rotation 603, which is also referred to as a tilt axis. This second movement unit 602 serves to tilt the object 125, 425 about the first stage axis of rotation 603.

Arranged on the second movement unit 602, in turn, is a third movement unit 604 that is designed as a guide for a slide and that ensures that the object holder 114 is movable in the x-direction (first stage axis). The aforementioned slide is a further movement unit in turn, specifically a fourth movement unit 605. The fourth movement unit 605 is designed in such a way that the object holder 114 is movable in the y-direction (second stage axis). To this end, the fourth movement unit 605 has a guide in which a further slide is guided, a holder 609 with the object holder 114 and the object 125, 425 in turn being arranged on the latter.

The holder 609 is designed, in turn, with a fifth movement unit 606 that enables a rotation of the holder 609 about a second stage axis of rotation 607. The second stage axis of rotation 607 is oriented perpendicular to the first stage axis of rotation 603.

On account of the above-described arrangement, the sample stages 122, 424 of the embodiment discussed here have the following kinematic chain: first movement unit 600 (movement along the z-axis)—second movement unit 602 (rotation about the first stage axis of rotation 603)—third movement unit 604 (movement along the x-axis)—fourth movement unit 605 (movement along the y-axis)—fifth movement unit 606 (rotation about the second stage axis of rotation 607).

In a further embodiment (not depicted), provision is made for further movement units to be arranged at the sample stage 122, 424 such that movements along further translational axes and/or about further axes of rotation are made possible.

It is clear from FIG. 6 that each of the aforementioned movement units is connected to a stepper motor. Thus, the first movement unit 600 is connected to a first stepper motor M1 and driven on account of a driving force that is provided by the first stepper motor M1. The second movement unit 602 is connected to a second stepper motor M2, which drives the second movement unit 602. The third movement unit 604 is connected, in turn, to a third stepper motor M3. The third stepper motor M3 provides a driving force for driving the third movement unit 604. The fourth movement unit 605 is connected to a fourth stepper motor M4, with the fourth stepper motor M4 driving the fourth movement unit 605. Further, the fifth movement unit 606 is connected to a fifth stepper motor M5. The fifth stepper motor M5 provides a driving force that drives the fifth movement unit 606. The aforementioned stepper motors M1 to M5 are controlled by a control unit 608 (cf. FIG. 6).

As already mentioned above, the SEM 100, the combination apparatus 200 and/or the particle beam apparatus 400 can be designed as the material processing device 2000. In this case, the SEM 100, the combination apparatus 200, and/or the particle beam apparatus 400 has or have all features explained herein with respect to the material processing device 2000.

Embodiments of the system described herein are explained in more detail below in relation to the material processing device 2000 in the form of the combination apparatus 200. The system described herein is carried out in analogous fashion in relation to the SEM 100 and/or the particle beam apparatus 400.

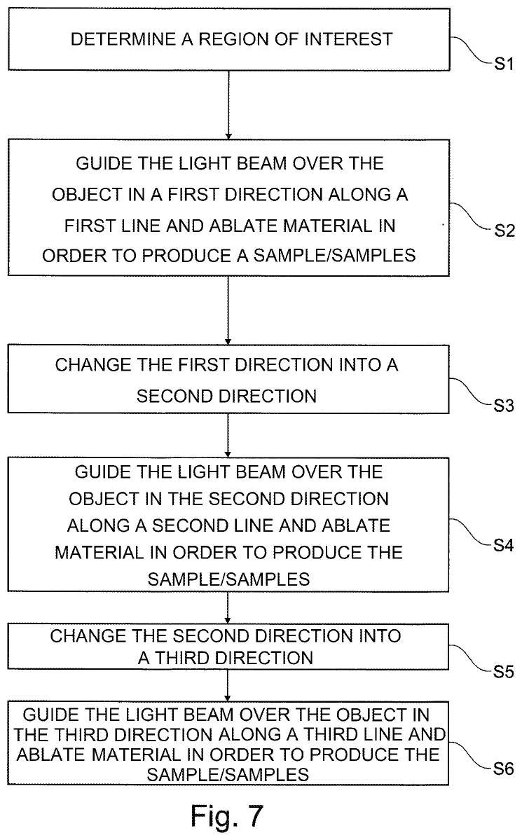

FIG. 7 shows a schematic representation of a procedure of one embodiment of the system described herein. In a method step S1, a region of interest of the object 125 arranged on or in the object 125 is determined using the determination device 2002 of the material processing device 2000. Expressed differently, the position of the region of interest is determined in or on the object 125. By way of example, the region of interest is a precipitate in the material of the object 125, a pore in the material of the object 125, an impurity phase in the material of the object 125, an interface in the material of the object 125 or a defect in the material of the object 125. By way of example, the region of interest is determined using the determination device 2002 with specified data about the object 125 or with data of a model of the object 125. By way of example, the embodiment of FIG. 7 is used if the structural build of the object 125 is known or approximately known. Then it is, for example, possible to accurately determine or approximately determine the position of the region of interest in or on the object 125. By way of example, the determined or suspected position of the region of interest is entered into the determination device 2002 and/or read from an external database. A further embodiment of the system described herein additionally or alternatively provides for the region of interest to be determined using the determination device 2002 using a non-destructive examination. By way of example, the region of interest is determined using the x-ray beam device, using the ultrasound device, and/or using the lock-in thermography device.

Once the region of interest has been determined, the latter is centered for example in respect of the light beam. By way of example, for centration purposes, use can be made of a method known from U.S. Pat. No. 8,693,008 B2, the entire content of which is incorporated in this patent application by reference. Additionally, provision is for example made for the light beam to be focused on the surface of the object 125. To this end, it is possible, for example, to determine the position of the region of interest, in particular its height, using the method known from U.S. Pat. No. 8,693,008 B2. The height is then used to adjust the focusing of the light beam on the surface of the object 125.

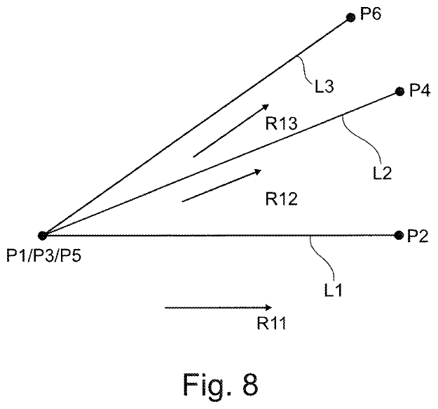

In method step S2, the light beam is guided over a surface of the object 125 in a first direction RI1 along a first line L1. This is depicted schematically in FIG. 8. The first line L1 runs from a first point P1 on the surface of the object 125 in the direction of a second point P2 on the surface of the object 125. By way of example, the light beam is guided over the surface of the object 125 using the guiding device 2003A. Additionally or as an alternative, provision is made for the object 125 to be moved with the sample stage 122 in relation to the light beam. Expressed differently, there is a relative movement of the light beam with respect to the object 125 in order to guide the the light beam. The relative movement is provided by moving the light beam and/or by moving the sample stage 122. Material of the object 125 is ablated when the light beam is guided over the surface of the object 125. Consequently, the light beam interacts with the material of the object 125. On account of the interaction of the light beam with the material of the object 125, the material on the object 125 is ablated such that the sample, or at least a part of the sample, is produced.

The direction of the movement of the light beam is changed in method step S3. More precisely, the first direction RI1 is changed into a second direction RI2 (cf. FIG. 8). By way of example, an axis of rotation intersects the first line L1. In particular, provision is made for the axis of rotation to run through the first point P1. FIG. 8 depicts in exemplary fashion that the axis of rotation runs through the first point P1 and perpendicular to the plane of the sheet. The first direction RI1 is changed into the second direction R12 by rotating the first line L1 about the axis of rotation on the surface of the object 125.

In an embodiment of the system described herein, provision is additionally or alternatively made for the first direction RI1 to be changed into the second direction R12 by rotating the first line L1 in a plane. By way of example, the first plane is the plane of the sheet of FIG. 8. However, the invention is not restricted thereto. Rather, any plane that is suitable for the invention can be used as a plane, that is to say also, by all means, a plane that does not correspond to the plane of the sheet of FIG. 8.

As is evident from FIG. 8, the first direction RI1 and the second direction R12 differ from one another. After changing the direction to the second direction RI2, the light beam is guided over the surface of the object 125 in the second direction RI2 along a second line L2.

The second line L2 runs from a third point P3, corresponding to the first point P1, on the surface of the object 125 in the direction of a fourth point P4 on the surface of the object 125. By way of example, the light beam is guided along the second line L2 using the guiding device 2003A. Additionally or as an alternative, provision is made for the object 125 to be moved with the sample stage 122 in relation to the light beam. Expressed differently, there is a relative movement of the light beam with respect to the object 125 in order to guide the light beam. The relative movement is provided by moving the light beam and/or by moving the sample stage 122.

Once again, material of the object 125 is ablated when the light beam is guided over the surface of the object 125 along the second line L2. Consequently, the light beam interacts with the material of the object 125 while the light beam is guided along the second line L2. On account of the interaction of the light beam with the material of the object 125, material on the object 125 is ablated such that the sample, or at least a part of the sample, is produced.

The direction of the movement of the light beam is changed in method step S5. More precisely, the second direction RI2 is changed into a third direction RI3 (cf. FIG. 8). By way of example, the axis of rotation intersects the second line L2. In particular, provision is made for the axis of rotation to run through the third point P3. FIG. 8 depicts in exemplary fashion that the axis of rotation runs through the third point P3 and perpendicular to the plane of the sheet. The second direction RI2 is changed into the third direction RI3 by rotating the second line L2 about the axis of rotation on the surface of the object 125.

In an embodiment of the system described herein, provision is additionally or alternatively made for the second direction RI2 to be changed into the third direction RI3 by rotating the second line L2 in the aforementioned plane. By way of example, the plane is the plane of the sheet of FIG. 8. However, the invention is not restricted thereto. Rather, any plane that is suitable for the invention can be used as a plane, that is to say also, by all means, a plane that does not correspond to the plane of the sheet of FIG. 8.

As is evident from FIG. 8, the second direction RI2 and the third direction RI3 differ from one another. After changing the direction to the third direction RI3, the light beam is guided over the surface of the object 125 in the third direction RI3 along a third line L3.

The third line L3 runs from a fifth point P5, corresponding to the first point P1 and the third point P3, on the surface of the object 125 in the direction of a sixth point P6 on the surface of the object 125. By way of example, the light beam is guided along the third line L3 using the guiding device 2003A. Additionally or as an alternative, provision is made for the object 125 to be moved with the sample stage 122 in relation to the light beam. Expressed differently, there is a relative movement of the light beam with respect to the object 125 in order to guide the light beam. The relative movement is provided by moving the light beam and/or by moving the sample stage 122.

Once again, material of the object 125 is ablated when the light beam is guided over the surface of the object 125 along the third line L3. Consequently, the light beam interacts with the material of the object 125 while the light beam is guided along the third line L3. On account of the interaction of the light beam with the material of the object 125, material on the object 125 is ablated such that the sample, or at least a part of the sample, is produced.

In the system described herein, provision is made for the light beam to be provided in pulsed fashion by the light beam device 2003. By way of example, the light beam is provided with pulse durations of the order of picoseconds or femtoseconds. The light beam device 2003 has a first operational state and a second operational state. In the first operational state, the pulsed light beam is guided to the surface of the object 125 in such a way that the light beam ablates the material from the object 125 for the purposes of producing the sample or at least a part of the sample. The light beam is not guided to the object 125 in the second operational state. Expressed differently, the second operational state is the state of the light beam device 2003 which occurs between the provision of the light beam for a first time interval and of the light beam for a second time interval. Expressed yet again differently, the light beam is initially provided during the first time interval. Then there is a time interval during which the light beam is not provided. Subsequently, the light beam is provided in the second time interval. The sample or at least a part of the sample is produced in the first operational state using the ablation of material from the object 125 on account of the interaction of the light beam with the object 125.

The invention is not restricted to guiding the light beam along the first line L1, along the second line L2, and along the third line L3. Rather, the light beam can be guided along numerous lines which emerge from changing directions between one line and a further line. In this respect, provision is made, for example, for method steps S3 and S4 and/or method steps S5 and S6 to be repeated as often as desired.

In yet a further embodiment of the system described herein, provision is additionally or alternatively made for a scanning region to be determined on the object 125, with the scanning region including a multiplicity of scan lines. In principle, the scan lines are lines, for example the first line L1, the second line L2 or the third line L3. The light beam is guided along the multiplicity of scan lines. By way of example, when the first direction is changed into the second direction, then the aforementioned scanning region rotates about the axis of rotation.

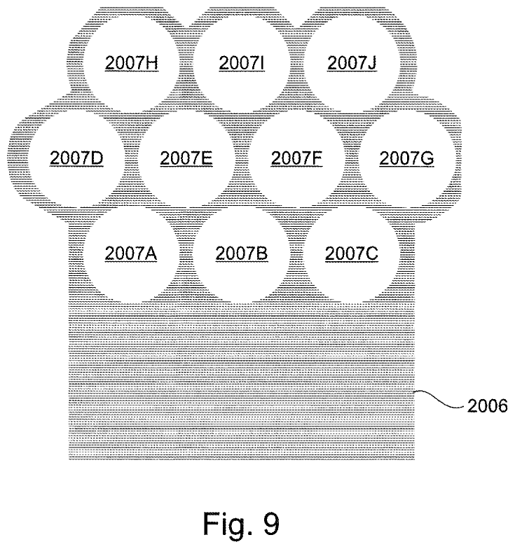

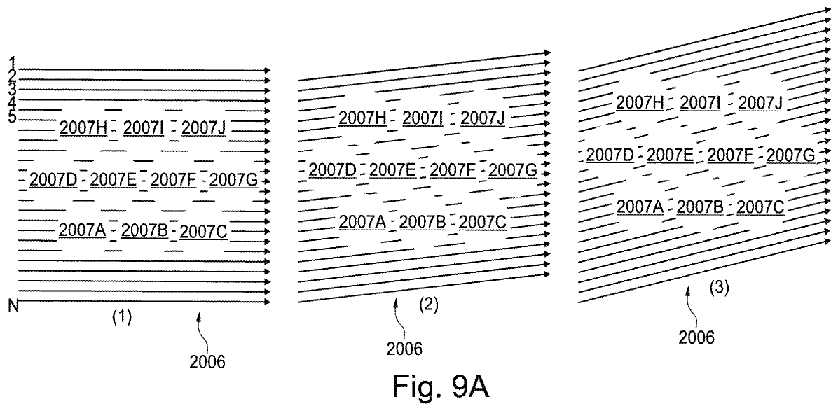

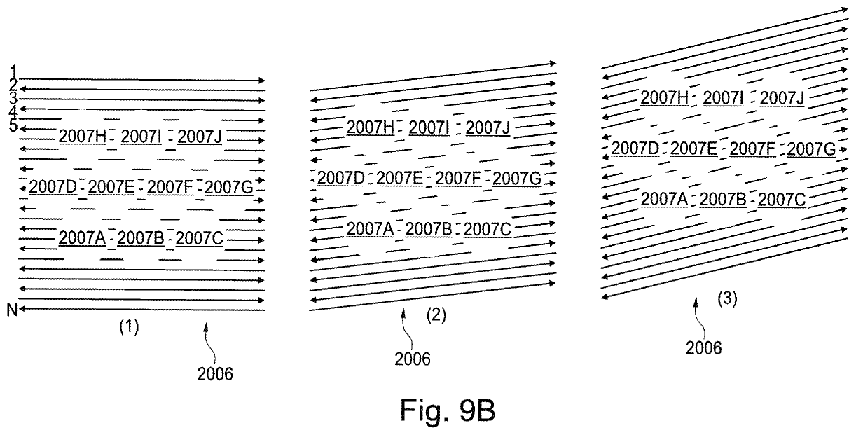

FIG. 9 shows an embodiment of a scanning region 2006 on the object 125. The scanning region 2006 has a multiplicity of scan lines in the form of lines. The light beam is guided along the lines. By way of example, when the first direction is changed into the second direction, then the aforementioned scanning region 2006 rotates about the axis of rotation in the embodiment of FIG. 9. As depicted in FIG. 9, the scanning region 2006 includes a first region 2007A, a second region 2007B, a third region 2007C, a fourth region 2007D, a fifth region 2007E, a sixth region 2007F, a seventh region 2007G, an eighth region 2007H, a ninth region 2007I, and a tenth region 2007J. The lines are interrupted in the aforementioned regions 2007A-2007J. In an embodiment of the system described herein, provision is made for a respective sample to be produced in each of the aforementioned regions 2007A-2007J. As explained above, the light beam device 2003 has the first operational state and the second operational state. In the first operational state, the pulsed light beam is guided to the surface of the object 125 in such a way that the light beam ablates the material from the object 125 for the purposes of producing the sample or at least a part of the sample. The light beam is not guided to the object 125 in the second operational state. The aforementioned regions 2007A-2007J are regions to which the light beam is not guided within the scope of the second operational state.

As explained above, provision is made, for example, for a scanning region 2006 to be determined on the object 125. The scanning region 2006 includes a multiplicity of scan lines. FIGS. 9A and 9B are based on FIG. 9. The same reference signs denote the same units. FIGS. 9A and 9B likewise show an embodiment of the scanning region 2006 on the object 125. The scanning region 2006 includes a multiplicity of scan lines in the form of lines 1 to N, where N is an integer. The light beam is guided along the multiplicity of scan lines. By way of example, the scan lines of the multiplicity of scan lines are arranged parallel to one another. In particular, provision is made for the light beam to initially be guided along two or more scan lines, preferably along all scan lines, of the scanning region 2006. By way of example, the light beam is guided along a scan line from a first scan line end to a second scan line end of the scan line (cf. FIG. 9A). In a further embodiment of the system described herein, provision is made for the light beam to be initially guided along a scan line from a first scan line end to a second scan line end of the scan line and to be subsequently guided along a further scan line from the second scan line end of the further scan line to the first scan line end of the further scan line. However, the invention is not restricted to such a guidance of the light beam over the scan lines. Rather, any type of guidance over the scan lines which is suitable for the invention can be used in the invention. When the first direction is changed into the second direction, then the scanning region 2006 rotates about the axis of rotation in the aforementioned embodiments of the system described herein, and so all scan lines are also rotated. The illustrations (2) in FIGS. 9A and 9B show the scanning region 2006 following a rotation of the scanning region 2006 of illustrations (1) in FIGS. 9A and 9B. Further, the illustrations (3) in FIGS. 9A and 9B show the scanning region 2006 following a rotation of the scanning region 2006 of illustrations (2) in FIGS. 9A and 9B. The rotation of the scanning region 2006 and the subsequent guidance of the light beam over the scan lines of the scanning region 2006 are repeated until the sample has been produced or the plurality of samples have been produced on the object 125.

Using the system described herein, it is possible to produce a single sample or a multiplicity of samples. In particular, provision is made for the multiplicity of samples to include at least 5 samples, at least 10 samples or at least 15 samples on the object 125. However, the invention is not restricted to the aforementioned number of samples. Instead, the multiplicity of samples may include any number of samples suitable for the invention. By way of example, a multiplicity of samples containing 10 samples, which are each arranged in one of the aforementioned regions 2007A-2007J, are produced using the scanning region 2006 depicted in FIG. 9.

By way of example, provision is made for the individual samples of the multiplicity of samples to be respectively produced in succession within the first operational state of the light beam device 2003. Expressed differently, one of the samples of the multiplicity of samples is produced first, followed by a further sample of the multiplicity of samples. The aforementioned is repeated until all samples of the multiplicity of samples have been produced. As an alternative, provision is made for a plurality of samples of the multiplicity of samples (or at least in each case some of a plurality of samples of the multiplicity of samples) to be produced in a single work step of the system described herein. In yet a further alternative, provision is made for all samples of the multiplicity of samples (or at least in each case some of all samples of the multiplicity of samples) to be produced in a single work step of the system described herein.

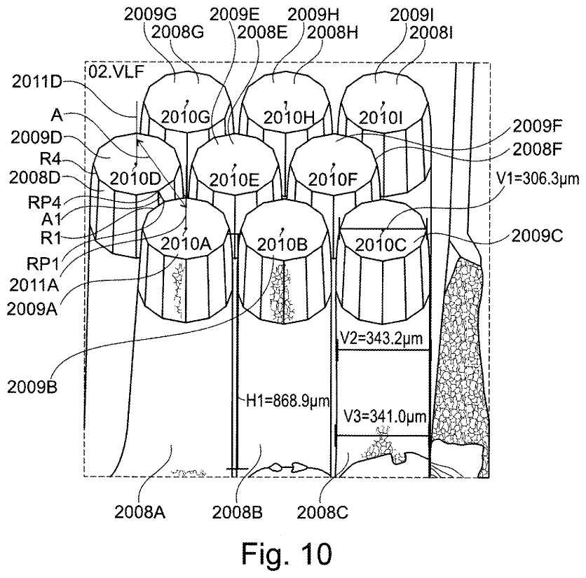

FIG. 10 shows a schematic representation of a multiplicity of samples, specifically a total of 9 samples: a first sample 2008A, a second sample 2008B, a third sample 2008C, a fourth sample 2008D, a fifth sample 2008E, a sixth sample 2008F, a seventh sample 2008G, an eighth sample 2008H, and a ninth sample 20081. The aforementioned samples 2008A-2008I may be produced using the system described herein. Each of the samples 2008A-2008I has a virtually cylindrical form. By way of example, the diameter of each of the produced cylindrical samples 2008A-2008I is between less than 1 μm and several 100 μm. The height of such a sample 2008A-2008I can range from several 10 μm to approximately 1 mm.

As is evident from FIG. 10, provision is made, for example, for each of the samples 2008A-2008I to have a respective face with a center. By way of example, each face is aligned parallel or substantially parallel to the surface of the object 125. Thus, the first sample 2008A has a first face 2009A and a first center 2010A, the second sample 2008B has a second face 2009B and a second center 2010B, the third sample 2008C has a third face 2009C and a third center 2010C, the fourth sample 2008D has a fourth face 2009D and a fourth center 2010D, the fifth sample 2008E has a fifth face 2009E and a fifth center 2010E, the sixth sample 2008F has a sixth face 2009F and a sixth center 2010F, the seventh sample 2008G has a seventh face 2009G and a seventh center 2010G, the eighth sample 2008H has an eighth face 2009H and an eighth center 2010H, and the ninth sample 2008I has a ninth face 2009I and a ninth center 2010I.

In the system described herein, the aforementioned samples 2008A-2008I are produced in such a way that mutually adjacent samples of the samples 2008A-2008I are at a certain distance from one another. In this case, adjacent samples are understood to mean samples between which no further sample of the multiplicity of samples is arranged. Expressed differently, a first sample and a second sample are arranged directly next to one another if no further sample is arranged between the first sample and the second sample. By way of example, the center of the face of one of the samples of the samples 2008A-2008I is at a distance from the center of the face of an adjacent sample of the samples 2008A-2008I, with the distance having at least one of the following features:
(i) the distance corresponds to a diameter or a multiple of the diameter of the light beam;
(ii) the distance is less than 900 μm, less than 800 μm, less than 700 μm, less than 600 μm, less than 500 μm, less than 400 μm, less than 300 μm, less than 200 μm, less than 100 μm, less than 80 μm, less than 60 μm, less than 50 μm, less than 30 μm, less than 20 μm, or less than 10 μm, for example.

With regard to the possible definitions of the diameter of the light beam, reference is made to the comments further above, which also apply here.

By way of example, the aforementioned distance is defined as set forth below. Running through the center of the face of a sample of the samples 2008A-2008I there is a first straight line, which is aligned perpendicular to the face of the sample, with the sample being adjacent to a further sample of the samples 2008A-2008I. Moreover, a second straight line, which is aligned perpendicular to the face of the further sample, runs through the center of the face of the further sample. The distance between the first sample and the further sample is the distance between the first straight line and the second straight line. By way of example, the distance is the length of a straight distance line, which intersects both the first straight line and the second straight line perpendicularly. As an alternative thereto, the distance is for example the minimum distance between the first straight line and the second straight line. The aforementioned is depicted in exemplary fashion in FIG. 10 with respect to the first sample 2008A and the fourth sample 2008D. The first sample 2008A has the first center 2010A, running through which there is a first straight line 2011A which is aligned perpendicular to the first surface 2009A. Moreover, the fourth sample 2008D has the fourth center 2010D, running through which there is a fourth straight line 2011D which is aligned perpendicular to the fourth surface 2009D. The distance between the first center 2010A and the fourth center 2010D is the length of a straight distance line A, which intersects both the first straight line 2011A and the fourth straight line 2011D perpendicularly. By way of example, the length of the straight distance line A corresponds to a diameter or a multiple of the diameter of the light beam. Additionally or as an alternative, the distance is less than 900 μm, less than 800 μm, less than 700 μm, less than 600 μm, less than 500 μm, less than 400 μm, less than 300 μm, less than 200 μm, less than 100 μm, less than 80 μm, less than 60 μm, less than 50 μm, less than 30 μm, less than 20 μm, or less than 10 μm, for example.

The distance between two adjacent ones of the samples 2008A-2008I may alternatively also be defined as follows: By way of example, the one sample of the samples 2008A-2008I (referred to as “this sample” below), which is adjacent to a further sample of the samples 2008A to 2008I (referred to as “further sample” below), has a first edge. Further, the further sample has a second edge. The distance between this sample and the further sample is the distance between the first edge and the second edge. By way of example, the distance is the length of a straight distance line, which runs from a first point on the first edge to a second point on the second edge. In particular, the distance is for example the minimum distance between the first edge and the second edge. The aforementioned is depicted in exemplary fashion in FIG. 10, once again with respect to the first sample 2008A and the fourth sample 2008D. The first sample 2008A has a first edge R1. Further, the fourth sample 2008D has a fourth edge R4. The distance between the first sample 2008A and the fourth sample 2008D is the minimum distance between the first edge R1 and the fourth edge R4. By way of example, the distance is the length of a straight distance line A1, which runs from a first point RP1 on the first edge R1 to a fourth point RP4 on the fourth edge R4. By way of example, the distance is less than 30 μm, less than 20 μm or less than 10 μm. Additionally or as an alternative, the distance corresponds to the diameter or a multiple of the diameter of the light beam.

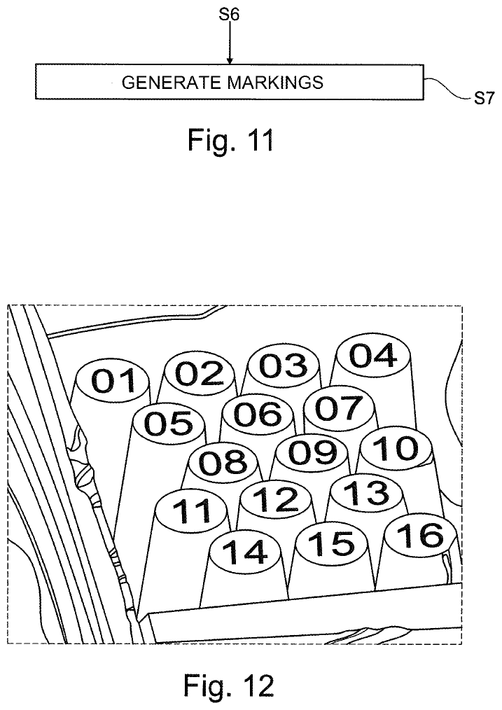

FIG. 11 shows a further step of a further embodiment of the method according to the system described herein. In a further method step S7 which follows method step S6, a respective marking is arranged on the face of each sample of the multiplicity of samples. By way of example, the marking is arranged on the face of each of the samples of the multiplicity of samples using the light beam, the electron beam, and/or the ion beam. FIG. 12 shows an embodiment of a multiplicity of samples, which total 16 samples. The faces of the samples are marked by numerals 1 to 16. The markings on the faces of the samples of the multiplicity of samples serve to render the individual samples uniquely identifiable.

In an embodiment of the system described herein, provision is additionally or alternatively made for the light beam to be guided over the surface of the object 125 in increments of less than 300 nm, less than 200 nm, or less than 100 nm.

It has been found that a sample that is as cylindrical as possible or a plurality of cylindrical samples is/are producible within a short period of time using the system described herein. In particular, it has been found that the use of pulsed light beams from the light beam device 2003 allows a sample to be formed as cylindrical as possible. Moreover, it has been found that the system described herein allows good simultaneous production of a plurality of cylindrical samples.

Once the cylindrical sample or the plurality of cylindrical samples are produced (for example, samples 2008A to 2008I), the cylindrical samples are separated from the object 125 in an embodiment of the system described herein. This is implemented using the ion beam in particular. Subsequently, the cylindrical sample or the plurality of cylindrical samples (for example, the samples 2008A-2008I) are analyzed. This is explained in more detail below in exemplary fashion on the basis of the samples 2008A-2008I.

By way of example, micromechanical properties of the material of the cylindrical samples 2008A-2008I are determined. In particular, the deformation of the cylindrical samples 2008A-2008I is measured by exerting pressure on a face of the cylindrical samples 2008A-2008I. Such a measurement is carried out using the combination apparatus 200, for example. To this end, the combination apparatus 200 includes an appropriate “in situ” measurement device. The measurement results determined are used in mathematical models in order to determine the mechanical material properties of the material of the cylindrical samples 2008A-2008I.

By way of example, provision is also made for the cylindrical samples 2008A-2008I to be examined using synchrotron radiation and for a sequence of projection images of the cylindrical samples 2008A-2008I from different directions to be created in the process. A three-dimensional structure of the interior of the cylindrical samples 2008A-2008I can be determined with high spatial resolution from the sequence of projection images. By way of example, such examinations are of interest when analyzing subcellular structures in biological samples.

Further, by way of example, provision is made for the cylindrical samples 2008A-2008I to be examined using x-ray radiation in order to create a sequence of projection images of the cylindrical samples 2008A-2008I from different directions. A three-dimensional structure of the interior of the cylindrical samples 2008A-2008I can be determined with low to mid spatial resolution from the sequence of projection images. By way of example, such examinations are of interest in the analysis of defects of microelectronic components or for the analysis of the porosity of biological or geological samples.

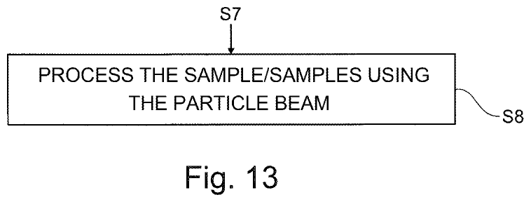

FIG. 13 shows a further method step S8 of an embodiment of the method according to the system described herein, which for example is carried out after method step S7. The samples 2008A-2008I are processed using the ion beam of the combination apparatus 200 in the method step S8. In principle, the embodiment of FIG. 13 accordingly provides for a production of the samples 2008A-2008I using the light beam to be followed by post-processing of the produced samples 2008A-2008I using the ion beam in order, where necessary, to bring the produced samples 2008A-2008I even closer to a cylindrical shape and/or to change the cylindrical form of the samples 2008A-2008I. By way of example, a tip is produced on the samples 2008A-2008I in this embodiment, in particular in order to enable examinations of the tip using atom probe tomography. With regard to atom probe tomography, reference is made to the comments made further above, which also apply here.

In yet a further embodiment of the system described herein, provision is additionally or alternatively made for a layer, for example a lacquer layer or an artificial resin layer, to be applied to the surface of the object 125. In particular, provision is made for the thickness of the layer to be substantially 10% to 20% of the height of the sample 2008A-2008I to be produced. In particular, provision is made for the layer to be applied in liquid form to the surface of the object 125. By way of example, the material of the layer is cured by the evaporation of a solvent contained in the material, by heating, and/or by irradiation with UV light over a certain period of time. In this embodiment of the system described herein, provision is now made for the previously applied layer to be removed again, for example using a solvent, after the sample 2008A-2008I is produced. It has been found that the cylindrical shape of the sample 2008A-2008I is obtainable particularly well using this embodiment of the system described herein.

None of the described embodiments of the method described herein are restricted to the aforementioned sequence of the explained method steps. Rather, any sequence of the aforementioned method steps suitable for the invention can be chosen.

The features of the invention disclosed in the present description, in the drawings and in the claims may be essential for the realization of the invention in the various embodiments thereof both individually and in arbitrary combinations. The invention is not restricted to the described embodiments. It can be varied within the scope of the claims and taking into account the knowledge of the relevant person skilled in the art.

1. A method for producing at least one sample on an object using a material processing device having at least one light beam device that provides at least one light beam, the method comprising:
guiding the light beam over a surface of the object in a first direction along a first line using a guiding device for the light beam and/or by moving the object using a movable object stage, on which the object is arranged, with material of the object being ablated when the light beam is guided over the surface of the object;
changing the first direction into a second direction by rotating the first line about an axis of rotation on the surface of the object; and
guiding the light beam over the surface of the object in the second direction along a second line, with the first direction differing from the second direction and with material of the object being ablated when the light beam is guided over the surface of the object along the second line, wherein
the light beam is provided in pulsed fashion by the light beam device and is guided onto the surface of the object in such a way that the light beam ablates material from the object in a first operational state of the light beam device and that the light beam is not guided onto the object in a second operational state, and wherein the sample is produced in the first operational state by ablating material from the object.

2. The method as claimed in claim 1, wherein the sample is a first sample and wherein at least one second sample is produced in the first operational state by ablating material from the object using the light beam.

3. The method as claimed in claim 2, wherein initially the first sample and then the second sample are produced in the first operational state.

4. The method as claimed in claim 2, wherein the first sample has a first face with a first center, wherein the second sample has a second face with a second center and wherein the first sample and the second sample are produced such that the first center is at a distance from the second center, wherein the distance has at least one of the following features:
the distance corresponds to a diameter or a multiple of the diameter of the light beam;
the distance is less than 900 μm, less than 800 μm, less than 700 μm, less than 600 μm, less than 500 μm, less than 400 μm, less than 300 μm, less than 200 μm, less than 100 μm, less than 80 μm, less than 60 μm, less than 50 μm, less than 30 μm, less than 20 μm, or less than 10 μm.

5. The method as claimed in claim 4, wherein a first marking is arranged on the first face of the first sample and/or a second marking is arranged on the second face of the second sample.

6. The method as claimed in claim 1, wherein the sample is part of a multiplicity of samples and wherein the multiplicity of samples are produced in the first operational state by ablating material from the object using the light beam.

7. The method as claimed in claim 6, wherein the multiplicity of samples include at least 5 samples, at least 10 samples or at least 15 samples on the object.

8. The method as claimed in claim 6, wherein the individual samples of the multiplicity of samples are respectively produced in succession in the first operational state of the light beam device.

9. The method as claimed in claim 6, wherein each sample of the multiplicity of samples has a respective face with a center and wherein the multiplicity of samples are produced such that a center of the face of at least one first sample of the multiplicity of samples is at a distance from the center of the face of at least one second sample of the multiplicity of samples, wherein the distance has at least one of the following features:
the distance corresponds to a diameter or a multiple of the diameter of the light beam;
the distance is less than 900 μm, less than 800 μm, less than 700 μm, less than 600 μm, less than 500 μm, less than 400 μm, less than 300 μm, less than 200 μm, less than 100 μm, less than 80 μm, less than 60 μm, less than 50 μm, less than 30 μm, less than 20 μm, or less than 10 μm, with no further sample of the multiplicity of samples being arranged between the first sample and the second sample.

10. The method as claimed in claim 9, wherein a respective marking is arranged on the face of each sample.

11. The method as claimed in claim 1, wherein the method has at least one of the following features:
the first direction is changed into the second direction by rotating the first line in a plane;
the first line runs from a first point on the surface of the object in the direction of a second point on the surface of the object, with the axis of rotation intersecting the first line.

12. The method as claimed in claim 1, wherein the axis of rotation is a first axis of rotation and wherein the method further comprises:
changing the second direction into a third direction, the second direction being changed into the third direction by rotating the second line about a second axis of rotation on the surface of the object; and
guiding the light beam over the surface of the object in the third direction along the third line, with the second direction differing from the third direction and with material of the object being ablated when the light beam is guided over the surface of the object along the third line.

13. The method as claimed in claim 12, wherein the second direction is changed into the third direction by rotating the second line in the plane.

14. The method as claimed in claim 1, wherein the light beam is guided over the surface of the object in increments of less than 300 nm, less than 200 nm, or less than 100 nm.

15. The method as claimed in claim 1, wherein the sample is processed using a particle beam, the particle beam being provided by a particle beam generator of the material processing device.

16. The method as claimed in claim 1, including one of the following features:
a laser beam is used as light beam, with the light beam device being designed as a laser beam device;
a pulsed laser beam is used as light beam, with the light beam device being designed as a laser beam device;
a laser beam of an ultrashort pulse laser beam device is used as light beam.

17. A non-transitory computer readable medium containing software, which can be loaded into a processor and which, when executed, causes a material processing device to produce at least one sample on an object by performing the following:
guiding a light beam of a light beam device of the material processing device over a surface of the object in a first direction along a first line using a guiding device for the light beam and/or by moving the object using a movable object stage, on which the object is arranged, with material of the object being ablated when the light beam is guided over the surface of the object;
changing the first direction into a second direction by rotating the first line about an axis of rotation on the surface of the object; and
guiding the light beam over the surface of the object in the second direction along a second line, with the first direction differing from the second direction and with material of the object being ablated when the light beam is guided over the surface of the object along the second line, wherein the light beam is provided in pulsed fashion by the light beam device and is guided onto the surface of the object in such a way that the light beam ablates material from the object in a first operational state of the light beam device and that the light beam is not guided onto the object in a second operational state, and wherein the sample is produced in the first operational state by ablating material from the object.

18. A material processing device for processing an object, comprising:
at least one light beam device for providing at least one light beam;
at least one guiding device for guiding the light beam and/or at least one movable object stage; and
at least one control device having a processor coupled to a non-transitory computer readable medium containing software which, when executed by the processor, produces at least one sample on the object by performing the following:
guiding the light beam over a surface of the object in a first direction along a first line using the guiding device and/or by moving the object using the movable object stage, on which the object is arranged, with material of the object being ablated when the light beam is guided over the surface of the object;
changing the first direction into a second direction by rotating the first line about an axis of rotation on the surface of the object; and
guiding the light beam over the surface of the object in the second direction along a second line, with the first direction differing from the second direction and with material of the object being ablated when the light beam is guided over the surface of the object along the second line, wherein the light beam is provided in pulsed fashion by the light beam device and is guided onto the surface of the object in such a way that the light beam ablates material from the object in a first operational state of the light beam device and that the light beam is not guided onto the object in a second operational state, and wherein the sample is produced in the first operational state by ablating material from the object.

19. The material processing device as claimed in claim 18, wherein the material processing device has one of the following features:
the light beam device is designed as a laser beam device and the light beam is embodied as a laser beam;
the light beam device is designed as a laser beam device and the light beam is embodied as a pulsed laser beam;
the light beam device is designed as an ultrashort pulse laser beam device and the light beam is embodied as a pulsed laser beam.

20. The material processing device as claimed in claim 18, wherein the material processing device has the following features:
at least one particle beam apparatus having at least one beam generator that generates a particle beam having charged particles,
at least one objective lens that focuses the particle beam onto the object,
at least one scanning device that scans the particle beam over the object,
at least one detector that detects interaction particles and/or interaction radiation resulting from an interaction of the particle beam with the object, and
at least one display device that displays an image and/or an analysis of the object.

21. The material processing device as claimed in claim 20, wherein the beam generator is designed as a first beam generator and the particle beam is embodied as a first particle beam with first charged particles, wherein the objective lens is designed as a first objective lens for focusing the first particle beam onto the object, and wherein the particle beam apparatus further includes:
at least one second beam generator that generates a second particle beam comprising second charged particles; and
at least one second objective lens that focuses the second particle beam onto the object.

22. The material processing device as claimed in claim 20, having at least one of the following features:
the particle beam apparatus is an electron beam apparatus and/or an ion beam apparatus;
the material processing device (2000) is designed as the particle beam apparatus.
